(19) United States
(12) Patent Application Publication
(10) Pub. No.: US 2026/0082533 A1
(43) Pub. Date: Mar. 19, 2026

(54) MEMORY STRUCTURES WITH MIDDLE STRAP CELLS

(71) Applicant: Taiwan Semiconductor Manufacturing Company, Ltd., Hsinchu (TW)

(72) Inventors: Ting-Yun Wu, Hsinchu City (TW); Lu Yang, New Taipei City (TW); Szuya Liao, Hsinchu City (TW)

(73) Assignee: Taiwan Semiconductor Manufacturing Company, Ltd., Hsinchu (TW)

(21) Appl. No.: 19/009,581

(22) Filed: Jan. 3, 2025

Related U.S. Application Data
(60) Provisional application No. 63/694,503, filed on Sep. 13, 2024.

(51) Int. Cl. H10B 10/00

(52) U.S. Cl. CPC H10B 10/125

(57) ABSTRACT

Cell designs are proposed for power distribution in a CFET SRAM device using middle strap cells to connect a backside of the device to a frontside thereof. A device includes a cell array disposed over a substrate. The cell array includes a first array portion and a second array portion separated along a first direction in a top view of the device. The device further includes a middle strap cell array disposed between the first array portion and the second array portion along the first direction. The middle strap cell array includes a plurality of middle strap cells arranged along a second direction perpendicular to the first direction in the top view. Each middle strap cell includes a via structure configured to deliver a reference voltage signal from a backside of the substrate to a frontside of the substrate.

### CROSS-REFERENCE TO RELATED APPLICATIONS

This application claims priority from U.S. Provisional Application No. 63/694,503, filed Sep. 13, 2024, the entire disclosure of which is incorporated herein by reference for all purposes.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, improved performance, and lower costs, challenges from both fabrication and design issues have resulted in the development of a number of three-dimensional designs including, for example, metal-oxide-semiconductor field effect transistors (MOS-FET), field effect transistors (FET), fin field effect transistor (FinFET), gate-all-around (GAA) devices (nanowires/nanosheets), GAA devices configured as complementary field effect transistor (CFET) devices, and multi-bridge channel field effect transistor (MBCFET) devices (nanosheets).

As integrated circuit (IC) technologies progress towards smaller technology nodes, memory or storage cells, such as static random access memory (SRAM) cells, often incorporate peripheral cells into their designs to enhance device performance, where each memory cell can store a bit of data. In one such examples, power tap cells have been implemented to facilitate delivery of power throughout the array of memory cells. While existing designs of power tap cells have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device having a vertically stacked structure, in accordance with some embodiments.

FIG. 2 illustrates a portion (e.g., a memory array) of the memory device as illustrated FIG. 1, in accordance with some embodiments.

FIG. 3A illustrates a three-dimensional perspective view of a memory cell in the portion of the memory device as illustrated in FIG. 2, in accordance with some embodiments.

FIG. 3B illustrates a circuit diagram corresponding to the memory cell as illustrated in FIG. 3A, in accordance with some embodiments.

FIG. 4 illustrates a block diagram of a memory device having a vertically stacked structure, in accordance with some embodiments.

FIG. 5 illustrates a frontside view of an example layout design of a portion of a memory device having a vertically stacked structure taken along a plane AA′ of FIG. 3A, in accordance with some embodiments.

FIG. 6 illustrates a backside view of an example layout design of the portion of the memory device taken along a plane BB′ of FIG. 3A and corresponding to FIG. 5, in accordance with some embodiments.

FIGS. 7, 11, 15, and 19 each illustrate a portion of the frontside view of the example layout design as illustrated in FIG. 5, in accordance with some embodiments.

FIGS. 8, 12, 16, and 20 each illustrate a portion of the backside view of the example layout design as illustrated in FIG. 6, in accordance with some embodiments.

FIGS. 9, 13, 17, and 21 each illustrate a cross-sectional view taken along a line CC′ of the portion of the example layout design as illustrated in FIG. 7 (or 8), 11 (or 12), 15 (or 16), and 19 (or 20), respectively, in accordance with some embodiments.

FIGS. 10, 14, 18, and 22 each illustrate a cross-sectional view taken along a line DD′ of the portion of the example layout design as illustrated in FIG. 7 (or 8), 11 (or 12), 15 (or 16), and 19 (or 20), respectively, in accordance with some embodiments.

FIG. 23 illustrates a flowchart of a method of manufacturing a semiconductor device, in accordance with some embodiments.

FIG. 24 illustrates a block diagram of a system of generating an IC layout design, in accordance with some embodiments.

FIG. 25 illustrates a block diagram of an IC manufacturing system, and an IC manufacturing flow associated therewith, in accordance with some embodiments.

FIG. 26 illustrates a flowchart of a method of manufacturing a memory device having a vertically stacked structure, in accordance with some embodiments.

FIG. 27 illustrates a flowchart of a method for implementing a portion of the method as illustrated in the flowchart of FIG. 26, in accordance with some embodiments.

FIGS. 28 and 29 each illustrate a three-dimensional perspective view of a portion of a memory cell in a memory device having a vertically stacked structure at an intermediate stage of the method illustrated in the flowchart of FIG. 27, in accordance with some embodiments.

FIGS. 30, 31, 32, and 33 each illustrate a cross-sectional view taken along line EE′ of a portion of the memory cell illustrated in FIG. 29 at an intermediate stage of the method illustrated in the flowchart of FIG. 27, in accordance with some embodiments.

FIGS. 34, 35, and 36 each illustrate a top view of a layout design of a portion of a middle strap cell in a memory device having a vertically stacked structure at an intermediate stage of the method illustrated in the flowchart of FIG. 26, in accordance with some embodiments.

FIGS. 37 and 38 each illustrate a cross-sectional view taken along line EE′ of the portion of the memory cell illustrated in FIG. 29 at an intermediate stage of the method illustrated in the flowchart of FIG. 26, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first are formed in direct contact the second features and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The structures and methods detailed below relate to improved structures, designs, and manufacturing methods for CFET IC devices. In some embodiments, a stack of semiconductor devices comprises a top or upper semiconductor device that is physically stacked over a bottom or lower semiconductor device along a vertical direction. A CFET structure includes stacked upper and lower semiconductor devices of different conductivity types. For simplicity, a stack of semiconductor devices is sometimes referred to as a device stack. Depending on the device design, the included device stacks comprise stacked semiconductor devices of the same conductivity type and/or device stacks in which the stacked semiconductor devices are of different conductivity types. For instances, an n-type metal-oxide-semiconductor (NMOS) transistor may be vertically stacked over a p-type metal-oxide-semiconductor (PMOS) transistor. In some embodiments, by configuring semiconductor devices in device stacks, the required chip area is reduced by up to 50%.

In some embodiments, semiconductor devices in a device stack are electrically coupled in series, which is advantageous in high voltage applications. In some embodiments, semiconductor devices in a device stack are electrically coupled in parallel, which is advantageous in high current applications. In at least one embodiment, device stacks are advantageously applicable to memory devices or memory regions of an IC device. Further benefits of device stacks, in one or more embodiments, include improvements in power, performance and/or area (PPA) of the resulting IC devices, or the like.

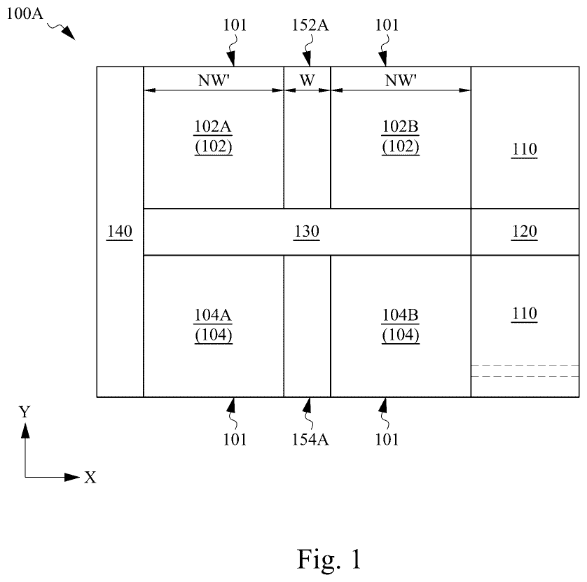

FIG. 1 illustrates an example block diagram of a semiconductor memory device 100A (hereafter referred to as a memory device 100A), in accordance with various embodiments. In some embodiments, the memory device 100A is a portion of an IC chip, a system on chip (SoC), or portion thereof, that includes various passive and active microelectronic devices, such as resistors, capacitors, inductors, diodes, transistors (e.g., p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, etc.), other suitable components, or combinations thereof.

The memory device (or macro) 100A includes one or more of an input/output (I/O) circuit 110, a control logic circuit 120, a word line (WL) driver 130, and a memory block 101, which includes a plurality of memory arrays, such as a first memory array 102 and a second memory array 104. In the present disclosure, the I/O circuit 110, the control logic circuit 120, and the word line driver 130 may be collectively referred to as the peripheral circuit of the memory device 100A. Despite not being explicitly shown in FIG. 1, the various components of the memory device 100A may be electrically (or operatively) coupled to each other and to the control logic circuit 120. For example, the I/O circuit 110, the control logic circuit 120, and the WL driver 130 may be electrically coupled to the memory block 101. Furthermore, although the components are shown in FIG. 1 as separate blocks for purposes of illustration, in some embodiments, some or all of the components may be integrated together.

In the present embodiments, the memory block 101 (e.g., the memory arrays 102 and 104 collectively) is formed over a substrate (e.g., a semiconductor substrate). The memory block 101 may be included in a microprocessor, a memory cell, and/or other IC device. In some embodiments, each memory array 102, 104 is electrically coupled to a corresponding I/O circuit 110. In this regard, each memory array 102, 104 may be disposed adjacent to the corresponding I/O circuit 110 along a first direction (e.g., X-direction). Furthermore, the memory arrays 102 and 104 may be arranged along a second direction (e.g., Y-direction) such that a boundary of the memory arrays abuts a vertical boundary of the I/O circuit 110. The control logic circuit 120 and the WL driver 130 may be electrically coupled to each of the memory arrays 102 and 104. It is noted that the arrangement of the various components of the memory device 100A is not limited to that depicted in FIG. 1, and components of the peripheral circuit of the memory device 100A may be positioned around and electrically coupled to the memory block 101 in a variety of suitable layout designs.

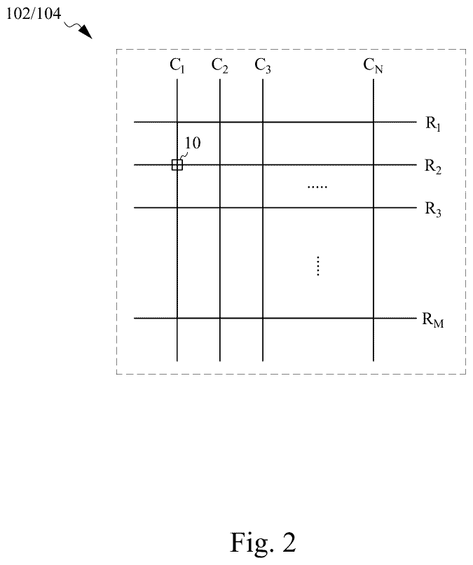

The memory array 102, 104 is configured as a hardware component that stores data. In one aspect, the memory array 102, 104 is embodied as a semiconductor memory device. Referring to FIG. 2, the memory array 102, 104 includes a plurality of memory cells (storage units or bit cells) 10. The memory array 102, 104 includes a number of rows R₁, R₂, R₃, R_{M}, each extending along the first direction and a number of columns C₁, C₂, C₃, C_{N}, each extending along the second direction. Each of the rows/columns may include one or more conductive structures. In some embodiments, each memory cell 10 is arranged in the intersection of a corresponding row and a corresponding column and can be operated according to voltages or currents through the respective conductive structures of the column and row.

In the present embodiments, the memory cells 10 are configured as static random-access memory (SRAM) cells, although the present disclosure may also be applicable to other types of memory cells. In addition, for purposes of discussion, each memory cell 10 includes transistors stacked along a third direction (e.g., Z-direction). In some embodiments, each memory cell 10 is configured with a CFET structure in which metal gate structures engage vertically stacked active regions to provide various vertically stacked transistors. In some examples, the memory cell 10 may additionally or alternatively include other types of FET structures, such as nanosheet FET, nanowire FET, gate-all-around (GAA) FETs, or the like.

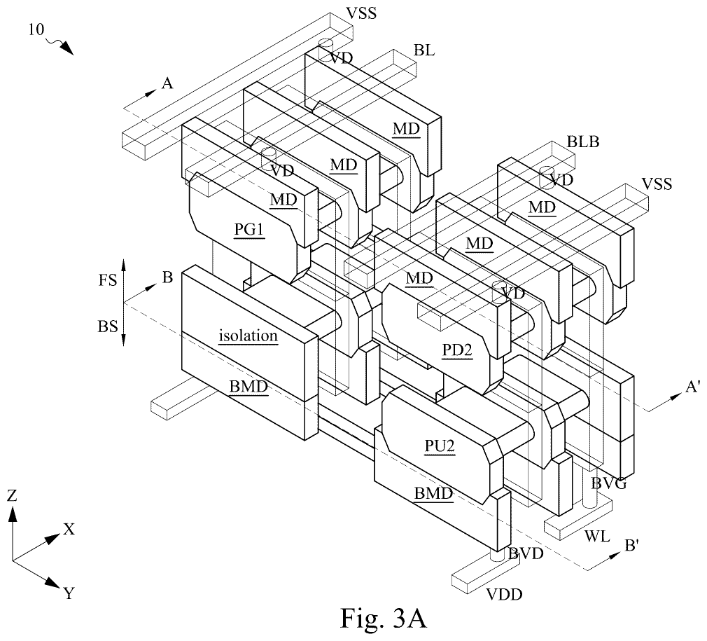

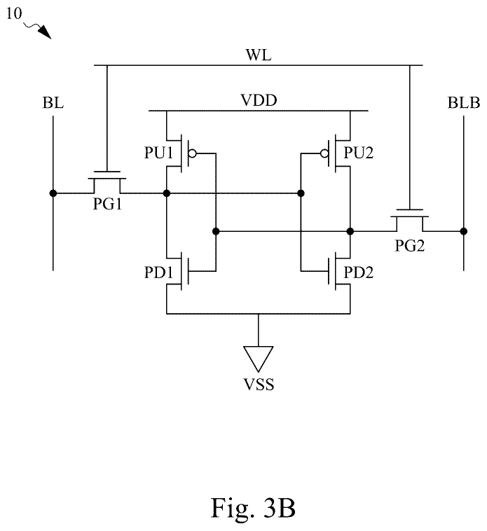

Referring to FIG. 3A, a three-dimensional perspective view of an embodiment of the memory cell 10 having a CFET structure is illustrated. In accordance with some embodiments of the present disclosure, the memory cell 10 includes six transistors (6T) and is therefore referred to as a 6T SRAM cell. In some examples, the memory cell 10 may be implemented as any of a variety of SRAM cells such as, for example, a two-transistor-two-resistor (2T-2R) SRAM cell, a four-transistor (4T)-SRAM cell, an eight-transistor (8T)-SRAM cell, a ten-transistor (10T)-SRAM cell, etc.

As shown in FIG. 3A, the memory cell 10 includes a first pull-up transistor (PU1; not shown in the perspective view depicted in FIG. 3A), a first pull-down transistor (PD1; not shown in the perspective view depicted in FIG. 3A), a second pull-up transistor (PU2), a second pull-down transistor (PD2), a first pass-gate transistor (PG1), and a second pass-gate transistor (PG2; not shown in the perspective view depicted in FIG. 3A). In some embodiments, the transistors PD1, PD2, PG1, and PG2 each include an NMOS transistor, and PU1 and PU2 each include a PMOS transistor.

Referring to FIGS. 3A and 3B collectively, the PU1 and PD1 are coupled to form a first inverter (or first cross-coupled inverter) and the PU2 and PD2 are coupled to form a second inverter (or second cross-coupled inverter), wherein the first and second inverters are cross-coupled to each other. Specifically, the first and second inverters are each coupled between a supply voltage (or a first supply voltage) VDD and ground (or a second supply voltage) VSS through respective frontside (FS) source/drain contacts (MDs) and frontside via contacts (VDs) or backside (BS) source/drain contacts (BMDs) and backside via contacts (BVDs). In addition to being coupled to the first and second inverters, the transistors PG1 and PG2 are each coupled to a word line (WL) through gate contacts, such as a backside gate contact (BVG). The transistors PG1 and PG2 are further coupled to a bit line (BL) and a bit bar line (BBL), respectively, through respective MDs and VDs. In the depicted embodiment, the memory cell 10 includes two ground VSS lines each extending along an edge of the memory cell in the first direction. In alternative embodiments, the memory cell 10 may include only one ground VSS line extending through a center of the memory cell 10 along the first direction and positioned between the BL and the BLB along the second direction. The ground VSS, BL, and BLB may each be configured as one of frontside M0 metal lines, which are disposed closest to the frontside of the substrate, and the WL and supply voltage VDD may each be configured as one of backside BM0 metal lines, which are disposed closest to the backside of the substrate.

In the present embodiments, referring to FIG. 3A, the PU1 and PD1, coupled together as the first inverter, are vertically stacked and aligned (e.g., channel regions aligned) along the third direction, and the PU2 and the PD2, coupled together as the second inverter, are vertically stacked and aligned along the third direction similar to the first inverter. In some embodiments, the PU1 and the PU2 are formed in lower active regions (or the lower tier of the CFET structure) extending along the first direction and spaced apart along the second direction. The lower active regions may be doped with an n-type dopant, such as phosphorus (P), arsenic (As), antimony (Sb), the like, or combinations thereof, to provide the PMOS transistors in the lower tier. Analogously, the PD1, PD2, PG1, and PG2 are formed in upper active regions (or the upper tier of the CFET structure) over the lower active regions, where the upper active regions extend along the first direction and are spaced apart along the second direction. The upper active regions may be doped with a p-type dopant, such as boron (B), aluminum (Al), indium (In), and gallium (Ga), the like, or combinations thereof, to provide the NMOS transistors in the upper tier. In some embodiments, the NMOS transistors are formed in the lower tier of the memory device 100A and the PMOS transistors are formed in the upper tier of the memory device 100A.

Referring back to FIG. 1, the WL driver 130, which may include a row decoder and a word line voltage supply unit, can be responsible for activating word lines within the memory arrays 102 and 104. When data needs to be read from or written to a row of the memory cells 10 (see FIG. 2) of the memory array 102, 104, the word line driver 130 may select the appropriate word line by driving it to a higher voltage level. The selected row of cells can then be read from or written to by sense amplifiers or write drivers connected to the bit lines, which run vertically and intersect with the word lines. The I/O circuit 110 is a hardware component that can access (e.g., read, program) each of memory cells asserted through an area decoder, such as the row decoder and a column decoder. The control logic circuit 120 is a hardware component that can control various coupled components of the memory device 100A (e.g., the components 110, 120, and 130).

Still referring to FIG. 1, for embodiments in which the memory block 101 of the memory device 100A includes arrays (102 and 104) of CFET-based memory cells 10, power (e.g., a reference voltage signal) may be delivered from one or more backside metal lines configured as portions of a power distribution network (PDN) to the frontside metal line(s) (e.g., the ground VSS) through a power tap cell 140. As such, the power tap cell 140 extends through the substrate, as well as multiple dielectric layers (e.g., frontside isolation layers including shallow trench isolations (STI), interlayer dielectric (ILD) layers, etc.), along the third direction. In various examples, power delivery by the power tap cell 140 relies on one or more via structures, such as a vertical local interconnect structure (VLI). Once the power is delivered to the frontside of the substrate, a plurality of frontside interconnect structures (e.g., contact features, vias, metal lines, etc.) are responsible for continued delivery throughout the memory block 101. In existing technologies, because the power tap cell 140 is positioned along an edge of the memory block 101, as depicted in FIG. 1, the memory device 100A consequently suffers large IR drop (e.g., large resistance and thus large) during the power delivery process, especially when sizes of the memory arrays 102 and 104, for example, and loading of the BL continue to increase at advanced technology nodes. Accordingly, improvement in power delivery system for CFET-based memory devices is desired.

The present disclosure provides memory devices configured to provide additional power delivery options using one or more power strap cells disposed within each memory array (e.g., the memory arrays 102 and 104), rather than solely relying on the edge-positioned power tap cell (e.g., the power tap cell 140). In contrast to the power tap cell 140, such power strap cells may be referred to as middle strap cells (MSCs) or in-array (as opposed to edge) strap cells. In various embodiments, by electrically coupling the PDN to the ground VSS through one or more VLIs (e.g., VLIs 60) within in-array strap MSCs (in addition and/or alternative to the edge-positioned power tap cell), a length of the power delivery route (e.g., through various interconnect structures) may be reduced, thereby decreasing the IR drop between the frontside and the backside and resulting in improvement in device performance.

For example, referring to FIG. 1 again, the memory device 100A further includes a first MSC array 152A and a second MSC array 154A extending from the first MSC array 152A along the second direction in the top view of the device 100A, where each of the first MSC array 152A and the second MSC array 154A includes a plurality of MSCs 150. In the present embodiments, as will be described in detail below, each MSC 150 includes one VLI 60, which may be positioned at a center of the MSC 150 along the first and the second direction.

In the depicted embodiments, the first MSC array 152A separates the first memory array 102 into a first array portion 102A and a second array portion 102B along the first direction. Analogously, the second MSC array 154A separates the second memory array 104 into a first array portion 104A and a second array portion 104B. In this regard, the first array portions 102A and 104A are aligned along the second direction, while the second array portions 102B and 104B are similarly aligned along the second direction.

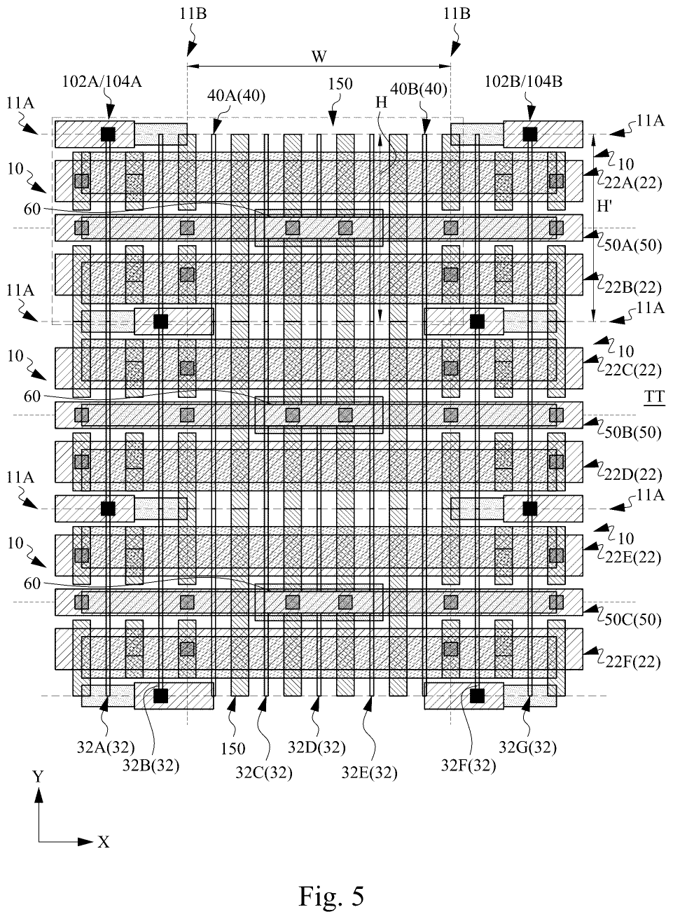

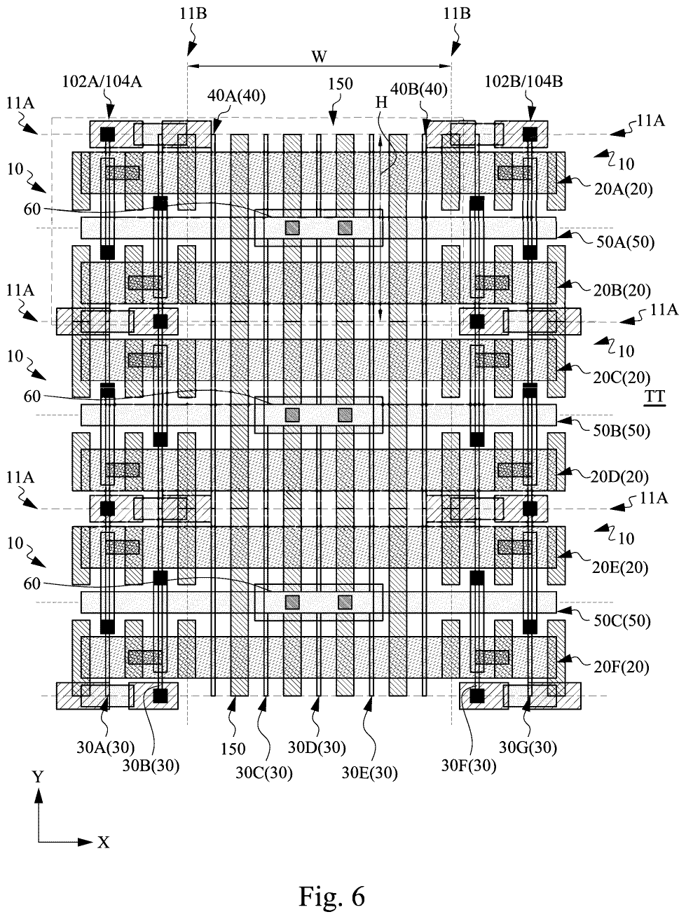

In the present embodiments, each MSC 150 of a given MSC array corresponds to and is horizontally aligned with a row of the memory cells 10 in the neighboring first and second memory array portions. For example, each MSC 150 in the first MSC array 152A is interposed between a memory cell 10 in the first array portion 102A and a memory cell 10 in the second array portion 102B along the first direction. In some embodiments, the plurality of MSCs 150 in each of the MSC array 152A and the second MSC array 154A are aligned along the second direction (see FIGS. 5 and 6) in the top view. Accordingly, the number of the MSCs 150 in each MSC array 152A and 154A corresponds to the number M of the rows of the memory cells 10 in the corresponding memory arrays 102 and 104, respectively, as depicted in FIG. 2. For example, the number of MSCs 150 (i.e., the number of the VLIs) in the first MSC array 152A corresponds to the number M of the rows of the memory cells 10 in the memory array 102, and the number of MSCs 150 in the second MSC array 154A corresponds to the number M of the rows of the memory cells 10 in the memory array 104.

Although the WL driver 130 depicted in FIG. 1 separates the first memory array 102 (and the portions thereof) and the second memory array 104 (and portions thereof) along the second direction, it is within the scope of the present disclosure that the memory arrays 102 and 104 are disposed adjacent one another along the second direction without any intervening component therebetween. Regardless of the arrangement of the components of the peripheral circuit, each of the MSC arrays 152A and 154A are disposed or interposed between two memory array portions along the first direction. Stated differently, each of the MSC arrays 152A and 154A has a first vertical boundary (i.e., extending along the second direction in the top view) that abuts a vertical boundary of a corresponding first array portion 102A or 104A, respectively, and a second vertical boundary that abuts a vertical boundary of a corresponding second array portion 102B or 104B, respectively. In contrast, only one of the vertical boundaries of the power tap cell 140 abuts the vertical boundary of the first array portion 102A or 104A such that the power tap cell 140 does not abut any vertical boundary of the second array portion 102B/104B.

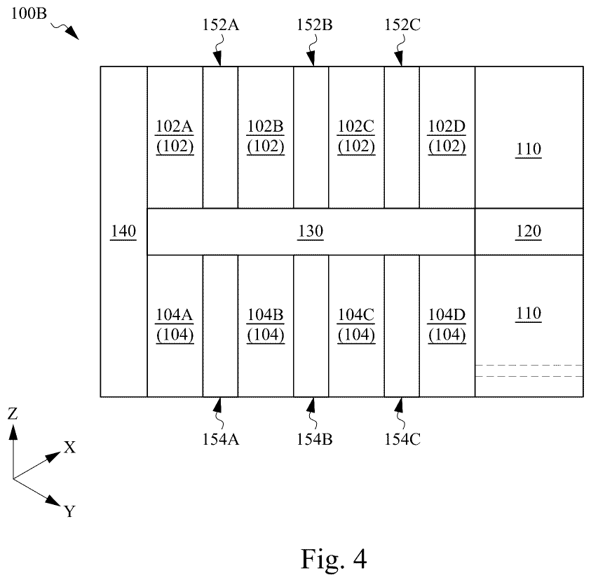

In some embodiments, as depicted in FIG. 1, the memory device 100A includes one MSC array (152A or 154A) in each memory array (102 or 104, respectively). In some embodiments, referring to FIG. 4, a semiconductor memory device 100B (hereafter referred to as a memory device 100B) similar to the memory device 100A is depicted and may include multiple MSC arrays in each memory array 102, 104. For example, the memory device 100B may include three MSC arrays 152A, 152B, and 152C (collectively referred to as MSC arrays 152) spaced along the first direction in the memory array 102 and three MSC arrays 154A, 154B, and 154C (collectively referred to as MSC arrays 154) spaced along the first direction in the memory array 104. In this regard, the multiple MSC arrays separate a given memory array into a plurality of portions, where a number of the array portions depends on a number of the MSC arrays included.

For example, in the depicted embodiment, the MSC arrays 152A-152C divide the memory array 102 into four array portions 102A, 102B, 102C, and 102D, while the MSC arrays 154A-154C divide the memory array 104 into four array portions 104A, 104B, 104C, and 104D. An increase in the number of the MSCs increases a number of the VLIs capable of transmitting the reference voltage signal from the backside to the frontside (e.g., to the ground VSS) of the memory device, further reducing the IR drop experienced during power distribution and improving the overall performance of the memory device.

FIG. 5 illustrates an example layout a portion of an upper tier of a semiconductor memory device 100C (hereafter referred to as a memory device 100C) taken along plane AA′ of FIG. 3A and FIG. 6 illustrates an example layout of a portion of a lower tier of the memory device 100C taken along plane BB′ of FIG. 3A, corresponding to the portion depicted in FIG. 5, in accordance with various embodiments. In the depicted embodiment, components of the memory device 100C that are similar to the memory device 100A or the memory device 100B are described using the same reference numerals for purposes of simplicity. It is noted that the peripheral circuit of the memory device 100B is omitted in FIGS. 5 and 6 in order to depict a portion of the memory block 101 in greater detail.

Referring to FIGS. 5 and 6 collectively, each of the first array portion 102A, 104A and the second array portion 102B, 104B is depicted with three example memory cells 10 arranged along the second direction. Each MSC 150 is interposed between and substantially aligned with a memory cell 10 in the first array portion 102A, 104A and a memory cell 10 in the second array portion 102B, 104B along the first direction. Three MSCs 150 are depicted in each of FIGS. 5 and 6 such that their respective VLIs 60 are substantially aligned along the second direction.

In the present embodiments, adjacent rows of the memory cells 10 and corresponding MSC 150 are separated by a horizontal boundary 11A (i.e., extending along the first direction in the top view). Each MSC 150 includes two vertical boundaries 11B extending along the second direction that separate the MSC 150 from the neighboring memory cells 10. In some embodiments, each VLI 60 is centered within the MSC 150 along both the first direction and the second direction, where the VLI 60 has a height H that is the same as a height H′ of each memory cell 10 along the second direction. The width W of the MSC 150 may be defined by a separation distance between the vertical boundaries 11B, which are positioned adjacent to two respective active region isolation structures 40A and 40B each extending along the second direction. In some embodiments, the active region isolation structures 40A and 40B are configured as a continuous polysilicon on diffusion edge (CPODE) structures. In some examples, the width W of each MSC 150 is at least about 5 center-poly pitch (CPP), with each of the active region isolation structures 40A and 40B being disposed 0.5 CPP away.

Referring to FIG. 5, for example, the memory device 100C includes a plurality of upper active regions 22A, 22B, 22C, 22D, 22E, and 22F (collectively referred to as upper active regions 22) each extending along the first direction and spaced apart along the second direction. The memory device 100C at the frontside further includes a plurality of metal gate structures 32A, 32B, 32C, 32D, 32E, 32F, and 32G (collectively referred to as metal gate structures 32) each extending along the second direction and spaced apart along the first direction. Each metal gate structure 32 engages the various upper active regions 22 to provide a plurality of NMOS transistors, such as the PG1, PG2, PD1, and PD2, in each memory cell 10 (see FIGS. 3A and 3B, for example). In this regard, the upper active regions 22 may be doped with a p-type dopant as described herein.

Still referring to FIG. 5, the memory device 100C further includes a plurality of gate isolation structures 50A, 50B, and 50C (collectively referred to as gate isolation structures 50) each extending along the first direction and interposed between two adjacent upper active regions 22 along the second direction. For example, the gate isolation structure 50A is interposed between the upper active regions 22A and 22B; the gate isolation structure 50B is interposed between the upper active regions 22C and 22D; and the gate isolation structure 50C is interposed between the upper active regions 22E and 22F. In the present embodiments, the gate isolation structure 50 is configured to truncate (cut or isolate) each metal gate structure 32 into separation portions along the second direction.

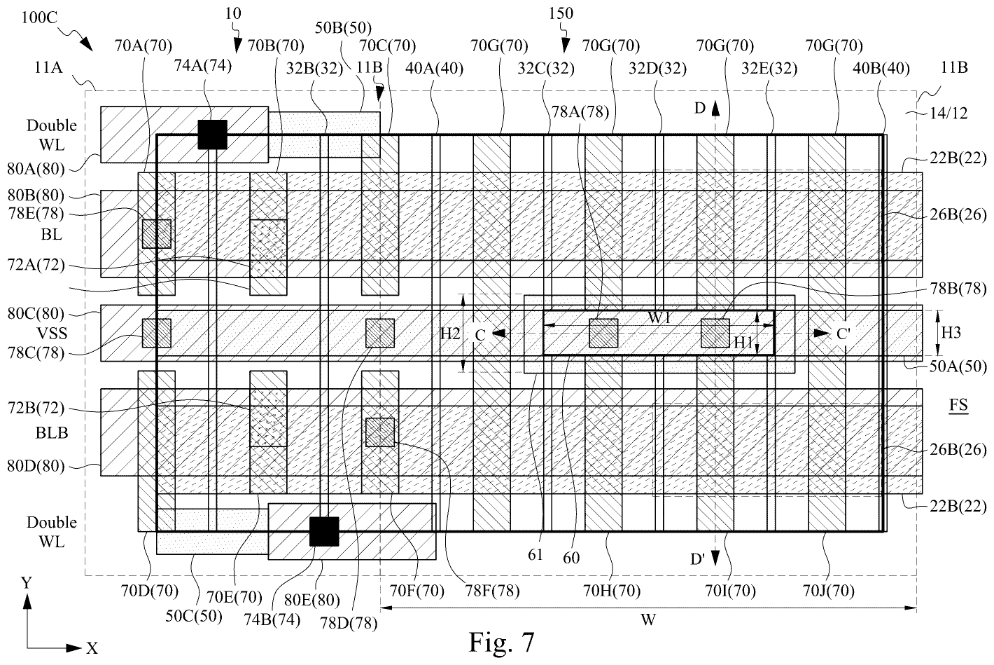

As depicted herein, still referring to FIG. 5, the upper active regions 22 and the gate isolation structures 50 extend across each first array portion 102A, 104A, the corresponding MSC array 152, 154, and the corresponding second array portion 102B, 104B along the first direction. In this regard, each VLI 60 is formed over a portion of the gate isolation structure 50 between two adjacent upper active regions 22 in the MSC 150. In the present embodiments, the gate isolation structures 50, and the respective VLIs 60 formed thereover, each extend to a substrate (e.g., substrate 12 described in reference to FIG. 7, for example) of the memory device 100C and through both the upper tier and the lower tier along the third direction. In the present embodiments, each VLI 60 further extends through the substrate along the third direction to electrically couple the conductive structures (e.g., backside metal lines 90) formed on the backside of the substrate, such as the PDN, to the frontside metal lines (e.g., frontside metal lines 80). As described herein, introducing multiple VLIs 60 in the in-array MSCs 150 provide additional conductive paths for transmitting power (i.e., a reference voltage signal) from the backside of the substrate to the frontside of the substrate, thereby lowering the IR drop between the frontside and the backside of the memory device.

Referring to FIG. 6, analogously, the memory device 100C includes a plurality of lower active regions 20A, 20B, 20C, 20D, 20E, and 20F (collectively referred to as lower active regions 20) each extending along the first direction and spaced apart along the second direction. The memory device 100C at the backside further includes a plurality of metal gate structures 30A, 30B, 30C, 30D, 30E, 30F, and 30G (collectively referred to as metal gate structures 30) each extending along the second direction and spaced apart along the first direction. Each metal gate structure 30 engages the various lower active regions 20 to provide a plurality of PMOS transistors, such as the PU1 and PU2, in each memory cell 10 (see FIGS. 3A and 3B, for example). In this regard, the lower active regions 20 may be doped with an n-type dopant as described herein.

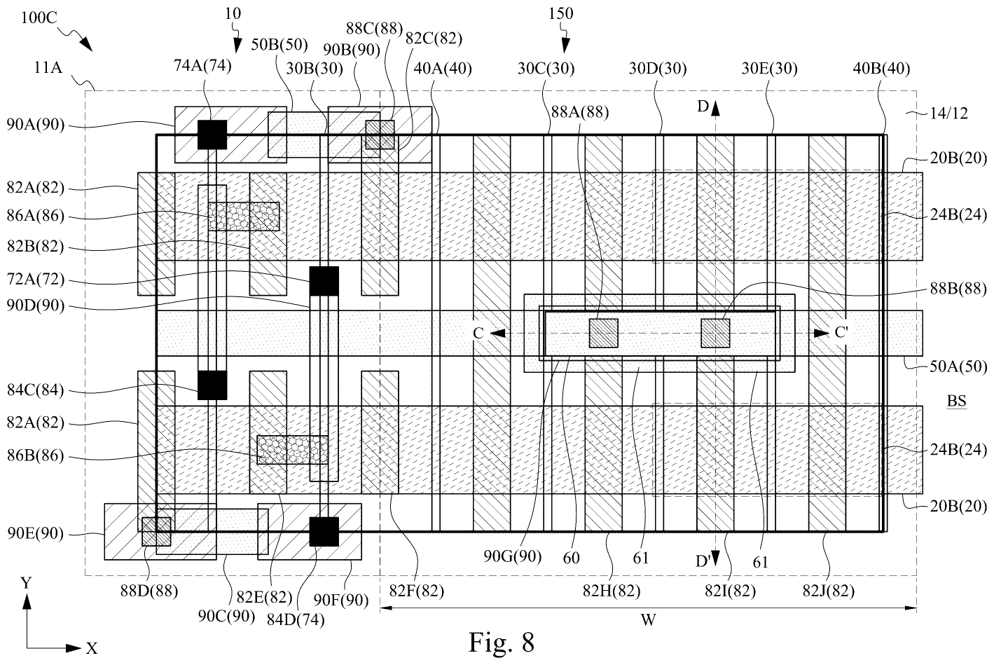

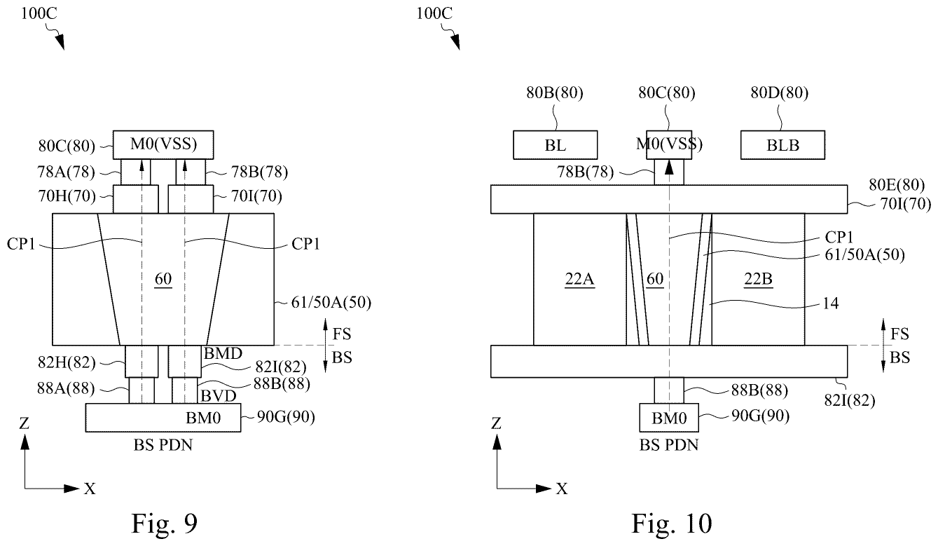

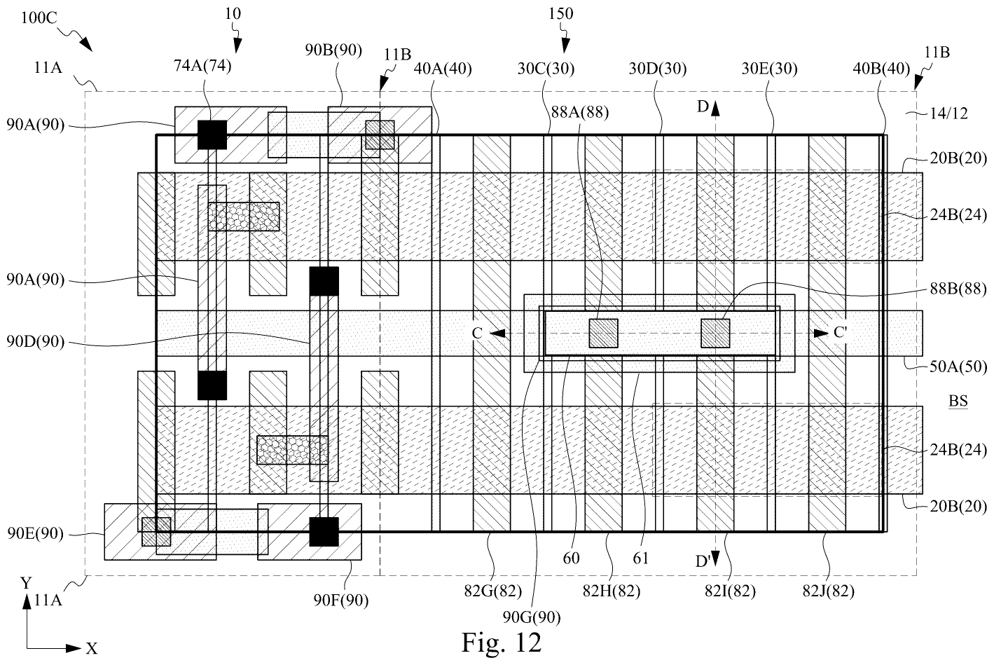

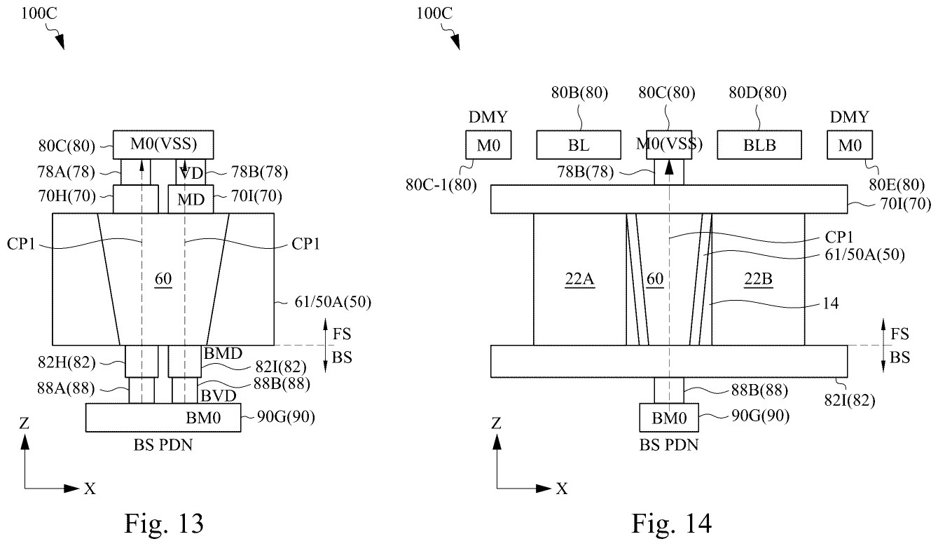

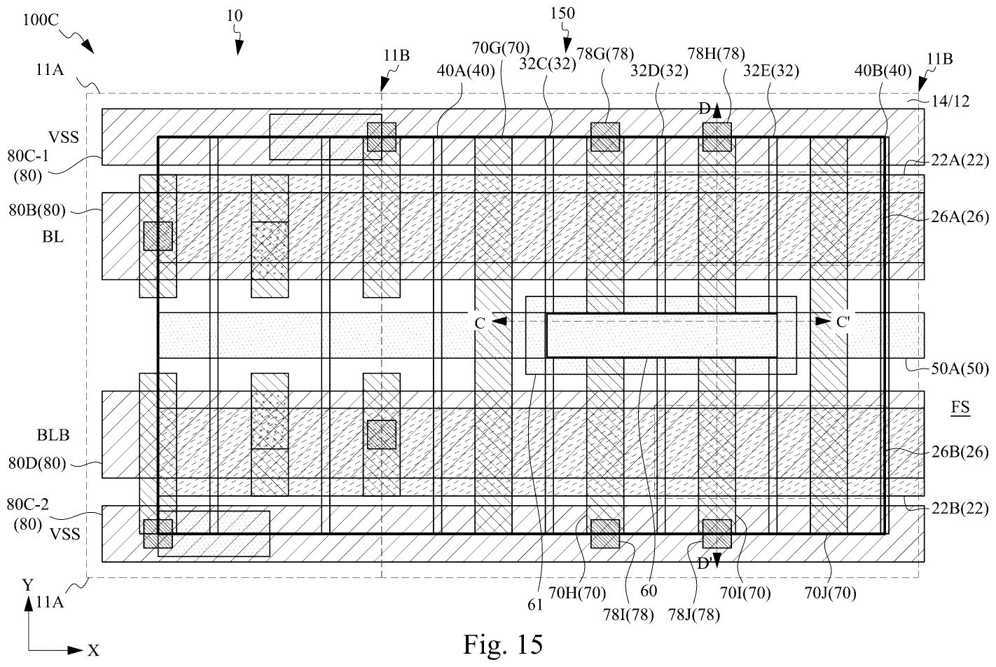

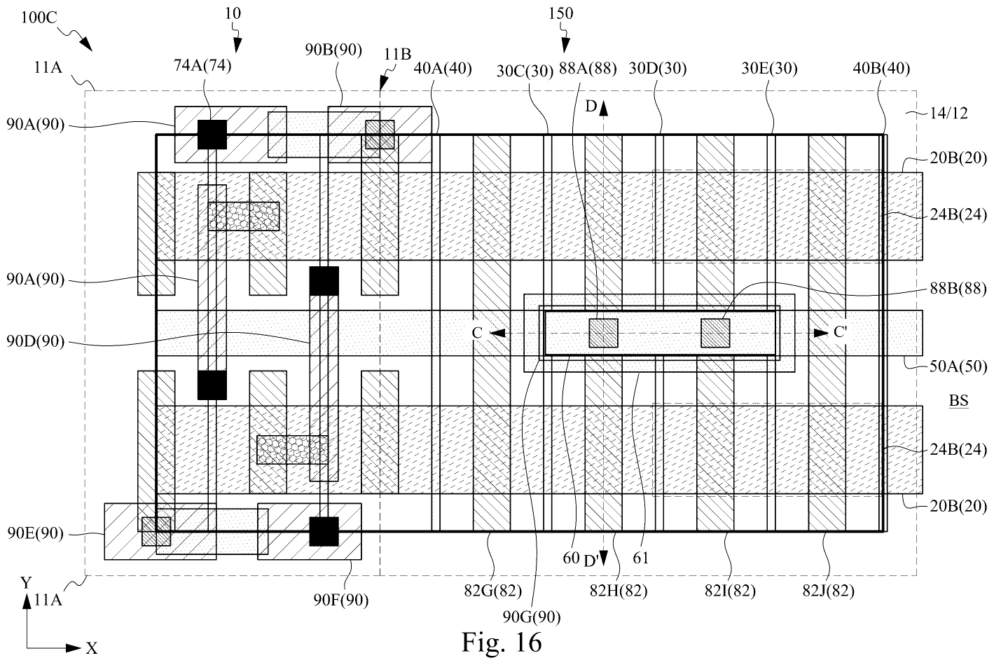

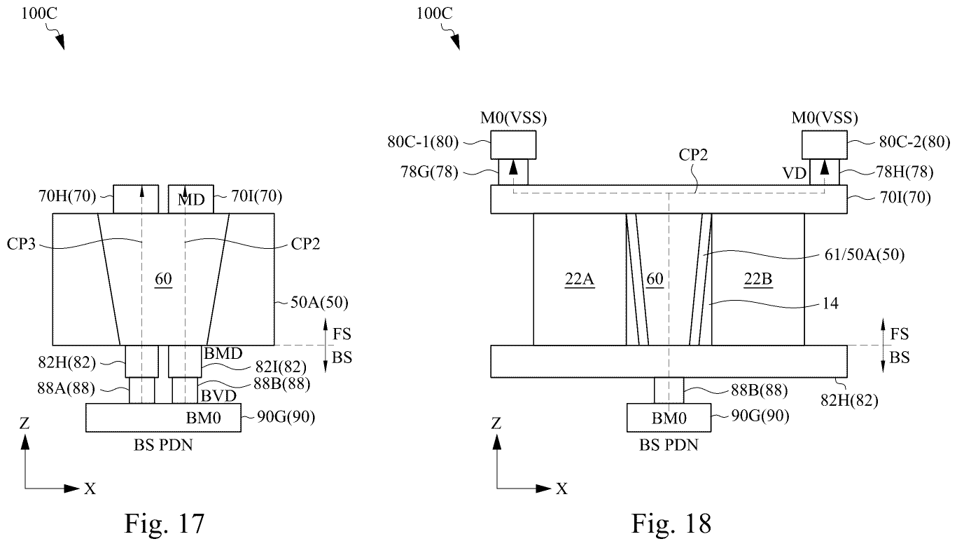

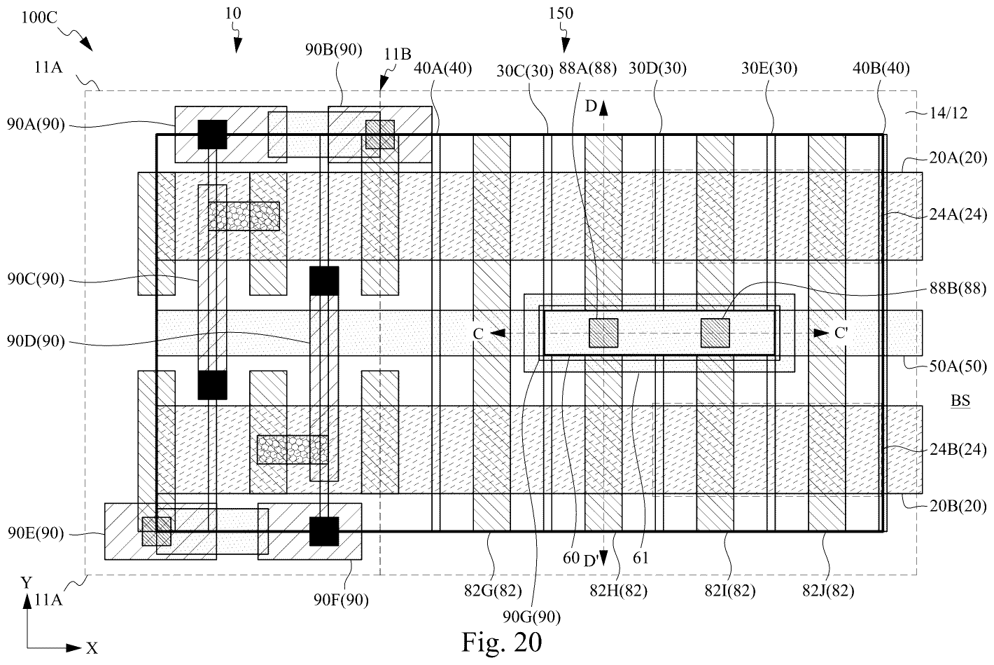

Components of the memory device 100C are described in detail below with reference to FIGS. 7-22. In particular, FIGS. 7, 11, 15, and 19 each illustrate a portion of the memory device 100C enclosed within dotted line in FIG. 5 (i.e., an example layout of the memory device 100C taken along the plane AA'); FIGS. 8, 12, 16, and 20 each illustrate an embodiment of the portion of the memory device 100C as depicted in FIG. 6 (i.e., an example layout of the memory device 100C taken along the plane BB′), corresponding to FIGS. 7, 11, 15, and 19, respectively; FIGS. 9, 13, 17, and 21 each illustrate a cross-sectional view of the portion of the memory device 100C taken along line CC′ as depicted in FIG. 7 (or 8), 11 (or 12), 15 (or 16), and 19 (or 20), respectively; and FIGS. 10, 14, 18, and 22 each illustrate a cross-sectional view of the portion of the memory device 100C taken along line DD′ as depicted in FIG. 7 (or 8), 11 (or 12), 15 (or 16), and 19 (or 20), respectively. The depicted portions of the memory device 100C in FIGS. 7-22 each include at least a portion of the memory cell 10 and a complete MSC 150 including a VLI 60. FIGS. 7, 11, 15, and 19 each illustrate a portion of the memory device 100C from a frontside view of the substrate 12, thereby illustrating at least the upper tier (see FIGS. 3A and 5, for example) of the memory device 100C, while FIGS. 9, 13, 17, and 21 each illustrate a portion of the memory device 100C from a backside view of the substrate 12, thereby illustrating at least the lower tier (see FIGS. 3A and 6, for example) of the memory device 100C.

Referring to FIGS. 7 and 8, the memory device 100C includes the substrate 12 underlying the various transistors described herein. In some embodiments, the substrate 12 includes an elementary semiconductor material such as silicon. In some embodiments, the substrate 12 includes a semiconductor-on-insulator (SOI) structure. For example, the substrate 12 may include a buried oxide (BOX) layer formed by a process such as separation by implanted oxygen (SIMOX) or other suitable technique, such as wafer bonding and grinding. The substrate 12 may include other suitable semiconductor materials.

The memory device 100C further includes isolation structures 14 disposed over the substrate 12. The isolation structures 14 may include shallow trench isolations (STIs) comprising an oxide, such as silicon oxide, a nitride, a low-k dielectric material (e.g., a dielectric material having a dielectric constant less than that of silicon oxide), the like, or combination thereof. The isolation structures 14 are configured to electrically isolate adjacent conductive features (e.g., upper active regions 22) formed over the substrate 12. In the view depicted in FIG. 7 and the like, the isolation structures 14 overlap portions of the substrate 12. Furthermore, each of the gate isolation structures 50, and thus the VLI 60 disposed therein, is formed over a portion of the isolation structures 14 between two adjacent (upper) active regions. In this regard, the VLIs 60 do not require additional device area to be allotted and can thus be readily integrated with existing device fabrication processes.

In the present embodiments, referring to FIG. 7, the upper active regions 22 each include a multilayer structure protruding from the substrate 12. Each upper active region 22 includes a plurality of nanosheets (or other suitable nanostructure such as nanowires or nanorods) stacked along the third direction and configured as channels of each of the transistors (e.g., the NMOS transistors) in the upper tier of the memory device 100C. The nanosheets in the upper active regions 22 may be doped with a p-type dopant to form the NMOS transistors described herein.

The metal gate structures 32 are formed over the substrate 12 and extend over the upper active regions 22 along the second direction. The metal gate structures 32 each include a gate electrode (not depicted) disposed over a gate dielectric layer (not depicted). In the present embodiments, a portion of each metal gate structure 32 wraps around the stack of the nanosheets in the upper active region 22 to form the transistors in the upper tier of the memory device 100C.

Analogously, referring to FIG. 8, the lower active regions 20 each include a multilayer structure protruding from the substrate 12 and surrounded by the isolation structures 14. Each lower active region 20 includes a plurality of nanosheets stacked along the third direction and configured as channels of each of the transistors (e.g., the PMOS transistors) in the lower tier of the memory device 100C. The nanosheets in the lower active regions 20 may be doped with an n-type dopant to form the PMOS transistors described herein. The metal gate structures 30 are formed below the corresponding metal gate structures 32 along the third direction and each include a gate electrode (not depicted) disposed over a gate dielectric layer (not depicted). A portion of each metal gate structure 30 wraps around the stack of the nanosheets in the lower active region 20 to form the transistors in the lower tier of the memory device 100C.

Referring to FIG. 7, the memory device 100C includes a plurality of source/drain features 26 (26A, 26B, etc.) adjacent to each metal gate structure 32 (i.e., adjacent to the stack of nanosheets in the upper active region 22). For example, the source/drain features 26A are formed adjacent to the stack of nanosheets in the upper active region 22A, and the source/drain features 26B are formed adjacent to the stack of nanosheets in the upper active region 22B. Analogously, referring to FIG. 8, the memory device 100C includes a plurality of source/drain features 24 (24A, 24B, etc.) adjacent to each metal gate structure 30 (i.e., adjacent to the stack of nanosheets in the lower active region 20). For example, the source/drain features 24A are formed adjacent to the stack of nanosheets in the lower active region 20A, and the source/drain features 24B are formed adjacent to the stack of nanosheets in the lower active region 20B.

For embodiments in which the transistors formed in the upper tier of the memory device 100C are configured as NMOS transistors (see FIG. 7), the source/drain features 26 may include silicon (Si) or silicon carbon (SiC) doped with an n-type dopant described herein. For embodiments in which the transistors formed in the lower tier of the memory device 100C are configured as PMOS transistors (see FIG. 8), the source/drain features 24 may include silicon germanium (SiGe) doped with a p-type dopant described herein.

Referring to FIGS. 7, 9, and 10, the memory device 100C further includes a plurality of frontside contact structures electrically coupling various components of the transistors in the upper tier to the frontside interconnect structures and further to the frontside metal lines. For example, the memory device 100C includes a plurality of frontside source/drain contacts 70A, 70B, 70C, 70D, 70E, 70F, 70G, 70H, 70I, and 70J (collectively referred to as frontside source/drain contacts 70) each extending along the second direction interposed or disposed between two adjacent metal gate structures 32 along the first direction. Each frontside source/drain contact 70 may be continuous across multiple upper active regions 22 (e.g., the frontside source/drain contact 70G) or across a single upper active region 22 (e.g., the frontside source/drain contact 70A) along the second direction. Each frontside source/drain contact 70 is electrically coupled to a source/drain feature 26. For example, the frontside source/drain contacts 70 may each be electrically coupled to one of the source/drain features 26A and/or to one of the source/drain features 26B. In some embodiments, the memory device 100C further includes inter-tier source/drain contacts 72A and 72B each electrically coupling one of the source/drain contacts 26 disposed in the upper tier to one of the source/drain contacts 24 disposed in the lower tier. The memory device 100C further includes a plurality of frontside gate contacts 74A and 74B (collectively referred to as gate contacts 74) each extending vertically along the third direction and electrically coupling one of the metal gate structures 32 to the frontside interconnect structures (e.g., frontside metal lines 80).

Furthermore, still referring to FIGS. 7, 9, and 10, the memory device 100C may include a plurality of frontside interconnect structures electrically coupled to the contact structures described herein. For example, the memory device 100C includes a plurality of frontside via contacts 78A, 78B, 78C, 78D, 78E, and 78F (collectively referred to as frontside via contacts 78). The frontside via contacts 78 each extending vertically along the third direction and electrically couple a contact structures (e.g., the frontside source/drain contacts 70, the frontside gate contacts 74, etc.) to one of the frontside metal lines 80A, 80B, 80C, 80D, and 80E (collectively referred to as frontside metal lines 80). The frontside metal lines 80 may be alternatively referred to as M0 metal lines as they are disposed in a metallization layer M0 closest to the frontside of the substrate 12.

Specifically, referring to FIG. 7, the frontside metal line 80C is configured as the ground VSS, which extends continuously through a center of the memory cell 10 and the MSC 150 along the first direction. In this regard, the frontside metal line 80C is equidistant to each of the horizontal boundaries 11A of the memory cell 10. In the present embodiments, the ground VSS is electrically coupled to the PDN disposed over the backside of the substrate 12 through at least the VLIs 60 disposed in the MSCs 150, one of which is depicted in FIGS. 7-10 and described in detail below. Furthermore, the metal lines 80B and 80D are configured as the BL and the BLB, respectively, and the metal lines 80A and 80E are configured as two frontside WLs, which are active metal lines. In some embodiments, at least some of the frontside source/drain contacts 70 are each electrically coupled to the one of the frontside metal lines 80 through a corresponding frontside via contact 78. Furthermore, the metal gate structures 32 provided in the memory cell 10 are each electrically coupled to one of the metal lines 80A and 80E through a corresponding gate contact 74.

Analogously, referring to FIG. 8, the memory device 100C further includes a plurality of backside source/drain contacts 82A, 82B, 82C, 82D, 82E, 82F, 82G, 82H, 82I, and 82J (collectively referred to as frontside source/drain contacts 82) each disposed on the backside of the substrate 12 and electrically coupled to one of the source/drain features 24. The memory device 100C includes a plurality of backside gate contacts 84A, 84B, 84C, and 84D (collectively referred to as backside gate contacts 84). In the present embodiments, the backside source/drain contacts 82 and the frontside source/drain contacts 70 are configured to have uniform dimensions and pitch or spacing along the first direction. The memory device 100C further includes a plurality of backside via contacts 88A, 88B, 88C, and 88D (collectively referred to as backside via contacts 88) electrically coupled to backside meta lines. The backside source/drain contacts 82 each electrically couple one of the source/drain features 24A and/or one of the source/drain features 24B to a corresponding one of the backside via contacts 88.

Still further, the memory device 100C includes a plurality of backside metal lines (e.g., the BM0 metal lines) 90A, 90B, 90C, 90D, 90E, 90F, and 90G (collectively referred to as backside metal lines 90). The backside via contacts 88 each electrically couple one of the backside source/drain contacts 82 to a corresponding one of the backside metal line 90, and the backside gate contacts 84 each electrically couple one of the metal gate structures 30 to a corresponding one of the backside metal line 90. Referring to FIGS. 7 and 8, the frontside metal lines 80 each extend along the first direction and are thus generally parallel to one another, while the backside metal lines 90 may extend in different directions. For example, the backside metal lines 90A and 90B each extend along the first direction and the backside metal lines 90C and 90D each extend along the second direction generally perpendicular to the backside metal lines 90A and 90B.

In some embodiments, the memory device 100C further includes backside via contacts 86A and 86B (collectively referred to as backside via contacts 86) each electrically coupling one of the backside source/drain contacts 82 to one of the backside metal lines 90. For example, the backside via contact 86A electrically couples the backside source/drain contact 82B to the backside metal line 90C, and the backside via contact 86B electrically couples the backside source/drain contact 82E to the backside metal line 90D. In some embodiments, the backside metal lines 90C and 90D are configured as the supply voltage VDD.

In various embodiments, each of the frontside/backside source/drain contacts 70/82, the inter-tier source/drain contacts 72, the frontside/backside gate contacts 74/84, the frontside/backside via contacts 78/86/88, and the frontside/backside metal lines 80/90 include a conductive material, such as tungsten (W), copper (Cu), cobalt (Co), ruthenium (Ru), aluminum (Al), titanium (Ti), tantalum (Ta), platinum (Pt), the like, or combinations (or alloys) thereof. In some embodiments, a barrier layer having TiN, TaN, or the like, a silicide layer having a metal silicide material such as NiSi, other suitable materials, or combinations thereof, may be included in one or more of the aforementioned contact structures, interconnect structures, and metal lines.

Furthermore, though omitted herein for purposes of simplicity, each of the aforementioned contact structures, interconnect structures, and metal lines may be formed or embedded in a dielectric layer that includes one or more of an interlayer dielectric (ILD) layer, a contact etch stop layer (CESL), the like, or combinations thereof, configured to electrically isolate the aforementioned structures from the surrounding conductive components.

As described herein, still referring to FIGS. 7 and 8, the active region isolation structures 40 each extend along the second direction and truncate the active regions 20 and 22 into separate portions. In various embodiments, each active region isolation structure 40 is positioned near the vertical boundary 11B of the MSC 150 to prevent or otherwise reduce shorting between each VLI 60 and the neighboring memory cells 10. In some embodiments, the active region isolation structure 40 is disposed 0.5 CPP away from the vertical boundary 11B. The gate isolation structures 50, on the other hand, each extend along the first direction and truncate the metal gate structures 30 and 32 into separate portions. In the embodiment depicted in FIGS. 7-10, the gate isolation structures 50 each extend through a center of the memory cells 10 such that the gate isolation structure 50 is equidistant to each horizontal boundary 11A of the memory cell 10. The active region isolation structures 40 and the gate isolation structures 50 may include any suitable dielectric material, such as silicon oxide, silicon nitride, the like, or combinations thereof.

In some embodiments, referring to FIGS. 7-10 collectively, the MSC 150 includes one VLI 60 corresponding to each neighboring memory cell 10 along the first direction. The VLI 60 is disposed in or over an extended portion 61 of one of the gate isolation structures 50 (e.g., the gate isolation structure 50A as depicted in FIGS. 7 and 8) that vertically extends through the center of the memory cell 10 and the MSC 150 along the third direction. In the depicted embodiment, the frontside metal line 80C configured as the ground VSS also extends through the center of the memory cell 10 and the MSC 150 such that the ground VSS is vertically aligned with at least a portion of the VLI 60 along the third direction.

The VLI 60 extends a width W1 along the first direction and a height H1 along the second direction in the top view. In some embodiments, portions of the gate isolation structure 50A adjacent to the extended portion 61 is defined by a height H3, while the extended portion 61 is defined by a height H2 that is greater than the height H1. In some embodiments, the height H1 and the height H3 are substantially the same. In some embodiments, the height H1 is greater than the height H3 but less than the height H2. While the present disclosure does not limit the VLI 60 to any specific dimensions, the width W1 may be kept at a minimum of about 2 CPP, i.e., across a minimum of three metal gate structures 32 on the frontside and three metal gate structures 30 on the backside, to reduce the overall area of the memory device 100C.

In the present embodiments, the VLI 60 extends along the third direction to electrically couple the frontside source/drain contacts 70 to the corresponding backside source drain contacts 82. For example, referring to FIGS. 7-10, the VLI 60 electrically couples a pair of two adjacent frontside source/drain contacts 70H and 70I to a corresponding pair of two adjacent backside source/drain contacts 82H and 82I. The frontside source/drain contacts 70H and 70I are further electrically coupled to the frontside metal line 80C, configured as the ground VSS, through the frontside via contacts 78A and 78B, respectively. Similarly, the backside source/drain contacts 82H and 82I are further electrically coupled to the backside metal line 90G, which is configured as a portion of the PDN, through the backside via contacts 88A and 88B, respectively. In this regard, the VLI 60 and the corresponding contact structures and interconnect structures on the frontside and backside of the substrate 12 allow power (i.e., the reference voltage signal) to be transmitted between the PDN (e.g., the backside metal line 90G) and the ground VSS (e.g., the frontside metal line 80C).

As depicted herein, the VLI 60 is embedded in or surrounded by the extended portion 61 of the gate isolation structure 50A such that the VLI 60 is electrically isolated from the neighboring upper active regions 22. Furthermore, as the VLI 60 is interposed between two adjacent upper active regions 22 along the second direction, the VLI 60 is disposed over and extends through a portion of the isolation structures 14 between the adjacent upper active regions 22. In various embodiments, the MSC 150 is substantially free of any electrical contact with the frontside/backside metal lines 80/90 except through the VLI 60 and its corresponding frontside/backside source/drain contacts 70/82 and frontside/backside via contacts 78/88. In the present embodiments, the MSC 150 does not include any electrical connection with the frontside metal lines 80 configured as the BL or the BLB, for example, or with the backside metal lines 80 configured as the supply voltage VDD or the WL. Specifically, the VLI 60 is electrically coupled to only the frontside metal line 80C, which is configured as the ground VSS, and the backside metal line 90G, which is configured as a portion of the PDN.

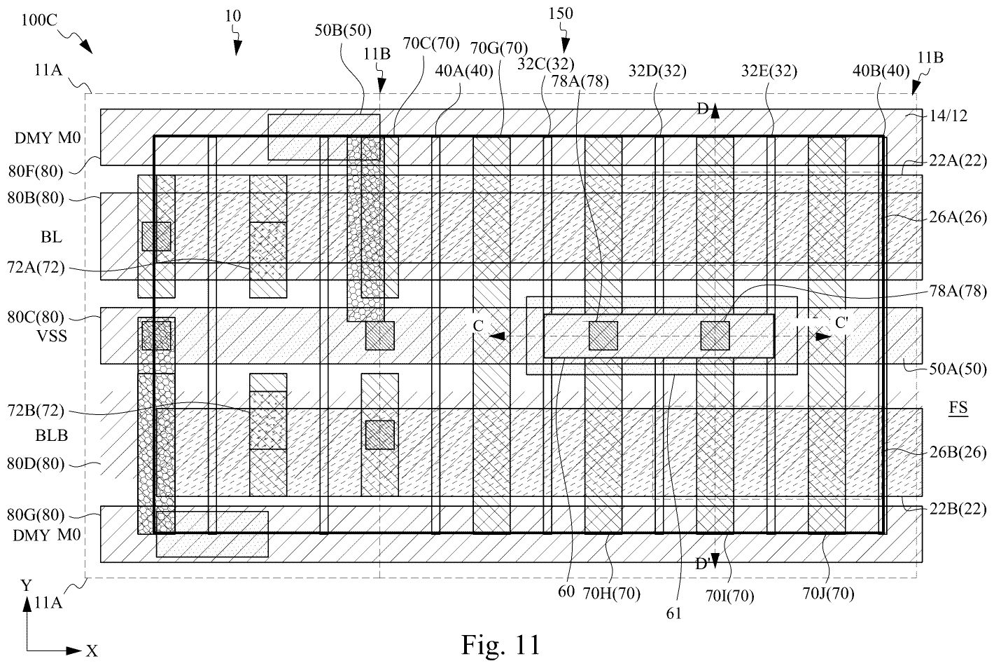

In some embodiments, instead of including two active frontside metal lines 80A and 80E, which may be configured as WLs of the memory cell 10, that extend along the respective horizontal boundaries 11A of the memory cell 10, the memory device 100C may include two inactive or dummy frontside metal lines in their places. For example, the embodiment of the memory device 100C depicted in FIGS. 11-14 is substantially similar to that of the memory device 100C depicted in FIGS. 7-10 with the exception that two dummy (DMY) frontside metal lines 80F and 80G replace the two active frontside metal lines 80A and 80E, respectively. In this regard, as depicted in FIG. 11, each of the dummy frontside metal lines 80F and 80G extends continuously across the memory cell 10 and the MSC 150 and is configured as a floating metal line not electrically coupled to any frontside via contacts 78, rendering it a dummy or inactive metal line with respect to the transistors formed in the upper tier of the memory cell 10. In some embodiments, as the dummy frontside metal lines 80F and 80G are each interposed between two BLs or two BLBs (e.g., the frontside metal line 80B/80D), respectively, of the adjacent memory cells 10, the dummy frontside metal lines 80F and 80G provide shield effect that can help reduce or prevent coupling between the BLs or the BLBs.

In some embodiments, instead of including a single frontside metal line 80C configured as the ground VSS of the memory cell 10 that extends through the center of the memory cell 10 and the MSC 150, the memory device 100C may include two separate frontside metal lines each configured as the ground VSS and extending along a boundary of the memory cell 10. For example, the embodiment of the memory device 100C depicted in FIGS. 15-18 is substantially similar to that of the memory device 100C depicted in FIGS. 7-10 with the exception that two frontside metal lines 80C-1 and 80C-2, each configured as the ground VSS, are disposed along the horizontal boundary 11A of the memory cell 10 and spaced apart along the second direction. Accordingly, each of the frontside metal lines 80C-1 and 80C-2 is shared between two adjacent memory cells 10 disposed along the second direction.

To accommodate connection to the frontside metal lines 80C-1 and 80C-2, referring to FIGS. 15-18, the memory device 100C includes two frontside via contacts 78G and 781, which are electrically coupled to respective end portions of the frontside source/drain contact 70H, and two frontside via contacts 78H and 78J, which are electrically coupled to respective end portions of the frontside source/drain contact 70I. Accordingly, the VLI 60 is electrically coupled to each of the frontside metal lines 80C-1 and 80C-2 through portions of the frontside source/drain contact 70H and 70I, which are subsequently coupled to each of the frontside metal lines 80C-1 and 80C-2 through the corresponding sets of the frontside via contacts 78G/78H and 781/78J.

Referring to FIG. 18, in contrast to extending directly along the third direction, the reference voltage signal (i.e., power) between the backside metal line 90G and each of the frontside metal lines 80C-1 and 80C-2 is transmitted along a two-dimensional conduction path CP2. For example, the conduction path CP2 first extends from the backside metal line 90G along the third direction through the backside via contact 88B and the VLI 60. The conduction path CP2 continues along the second direction through portions of each of the frontside source/drain contacts 70H and 70I towards their respective end portions. The conduction path CP2 continues to the corresponding frontside metal lines 80C-1 and 80C-2 through the frontside via contacts 78G/78H and 781/78J, respectively, along the third direction. In contrast, referring to FIGS. 7-14, a one-dimensional conduction path CP1 extends vertically from the backside metal line 90G to the frontside metal line 80C through the VLI 60, as well as the various frontside and backside contact structures and interconnect structures, along the third direction only.

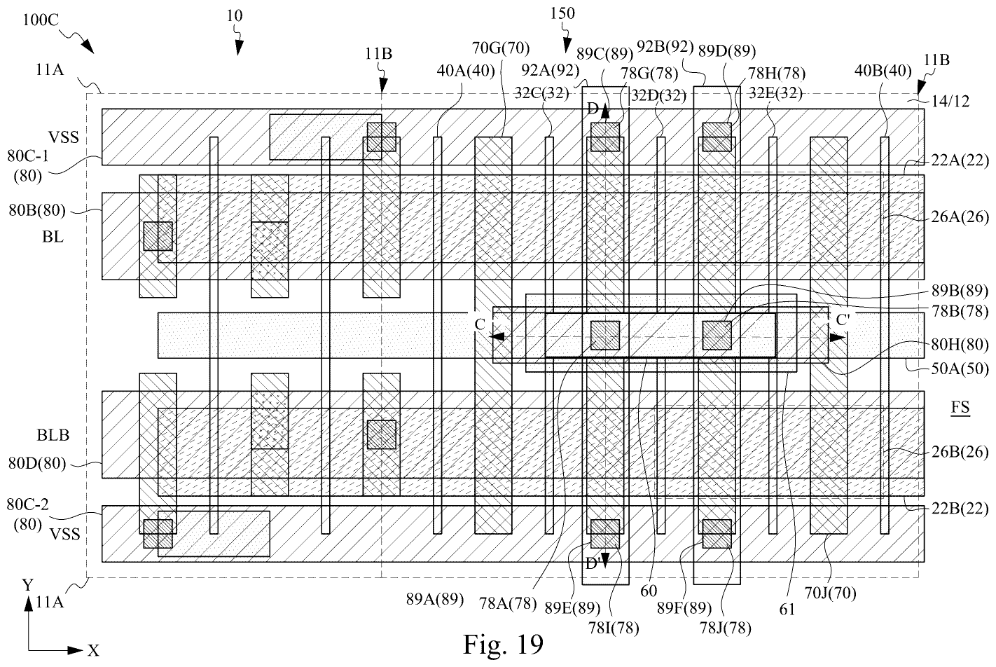

In some embodiments, the memory device 100C may include additional frontside interconnect structures and metal lines over the ground VSS to accommodate delivery of power from the backside PDN to the ground VSS. For example, the embodiment of the memory device 100C depicted in FIGS. 19-22 is substantially similar to that of the memory device 100C depicted in FIGS. 15-18 with the exception that each of the frontside metal lines 80H, 80C-1, and 80C-2 is coupled to frontside metal lines 92A and 92B (collectively referred to as frontside metal lines 92) through one or more of a plurality of frontside via contacts 89A, 89B, 89C, 89D, 89E, and 89F (collectively referred to as frontside via contacts 89). The frontside metal lines 92 may be alternatively referred to as M1 metal lines as they are disposed in a metallization layer M1 above or vertically stacked over the frontside metal lines 80 along the third direction, and the frontside via contacts 89 may be alternatively referred to as V0 via contacts.

In the depicted embodiment, the frontside via contacts 89A and 89B are electrically coupled to center portions of the frontside metal lines 92A and 92B, respectively, and are aligned with the VLI 60 along the third direction; the frontside via contacts 89C and 89E are electrically coupled to respective end portions of the frontside metal line 92A; and the frontside via contacts 89D and 89F are electrically coupled to respective end portions of the frontside metal line 92B. Accordingly, the frontside metal line 80H, which extends across the center of the memory cell 10 and the MSC 150 along the first direction, is electrically coupled to the frontside metal lines 92A and 92B through the frontside via contacts 89A and 89B, respectively; the frontside metal line 80C-1 is electrically coupled to the frontside metal lines 92A and 92B through the frontside via contacts 89C and 89D, respectively; and the frontside metal line 80C-2 is electrically coupled to the frontside metal lines 92A and 92B through the frontside via contacts 89E and 89F, respectively.

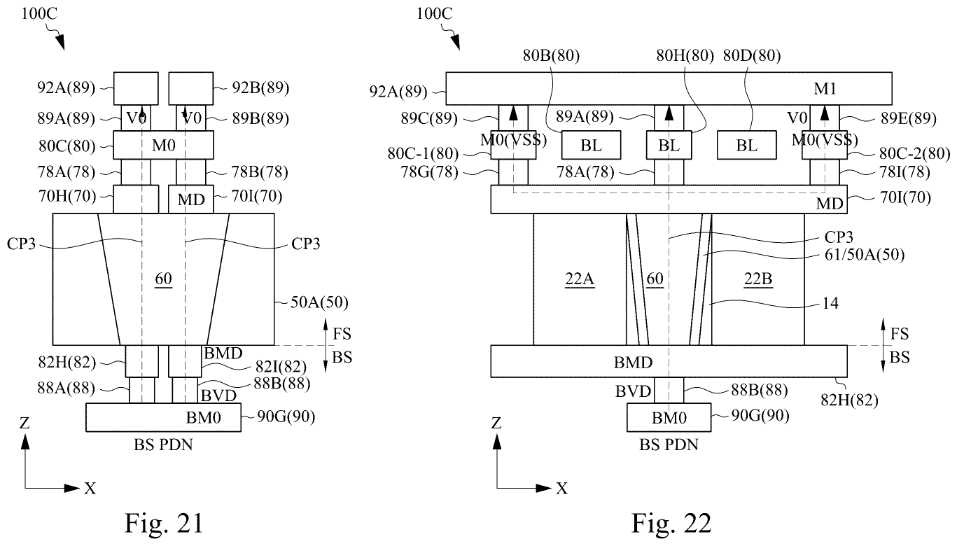

Referring to FIGS. 21 and 22, the reference voltage signal (i.e., power) between the backside metal line 90G and each of the frontside metal lines 80C-1 and 80C-2 is transmitted along a two-dimensional conduction path CP3, which is similar to the conduction path CP2 depicted in FIG. 18. For example, the conduction path CP3 first extends from the backside metal line 90G along the third direction through the backside via contact 88B and the VLI 60, and then continues along the second direction through portions of each of the frontside source/drain contacts 70H and 70I towards their respective end portions. However, different from the conduction path CP2, the conduction path CP3 is split between three different pathways extending along the third direction between each of the frontside source/drain contacts 70H and 70I and their corresponding, parallel-coupled frontside metal lines 92A and 92B through the corresponding frontside via contacts 78A, 78B, 78G, 78H, 78I, and 78J, the corresponding frontside metal lines 80H, 80C-1, and 80C-2, and the corresponding frontside via contacts 89A-89F. Accordingly, the reference voltage signal is delivered from the backside PDN to the ground VSS along multiple pathways, thereby lowering the overall IR drop along the conduction path CP3.

FIGS. 7-22 illustrate example embodiments in which the VLI 60 of the in-array MSC 150 may be electrically coupled to accommodate delivery of power from the PDN on the backside to the ground VSS on the frontside of the memory device 100C. It is noted that although only a first memory cell 10 (e.g., the memory cell 10 in the first array portion 102A, 104A of FIGS. 5 and 6) is depicted adjacent to the MSC 150 in FIGS. 7-22, various details presented herein are analogously applicable to a second memory cell 10 (e.g., the memory cell 10 in the first array portion 102B, 104B of FIGS. 5 and 6) adjacent to the MSC 150. For example, the various upper/lower active regions 22/20, frontside metal lines 80, and gate isolation structures 50, for example, also extend across the second memory cell 10. Specifically, the various transistors in the upper tier of the second memory cell 10 are also electrically coupled to the ground VSS, configured as the frontside metal line 80C, in manners analogous to those illustrated for the first memory cell 10.

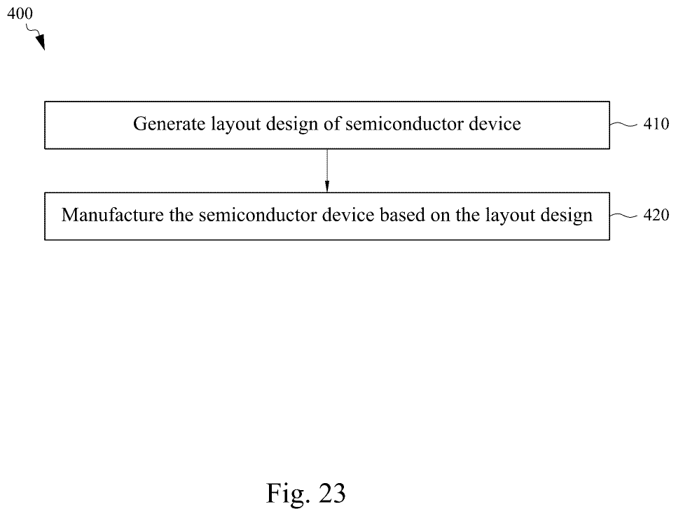

FIG. 23 is a flowchart of a method 400 of forming or manufacturing a semiconductor device, such as any of the memory devices 100A-100C, in portion or in entirety, in accordance with some embodiments. It is understood that additional operations may be performed before, during, and/or after the method 400 depicted in FIG. 23.

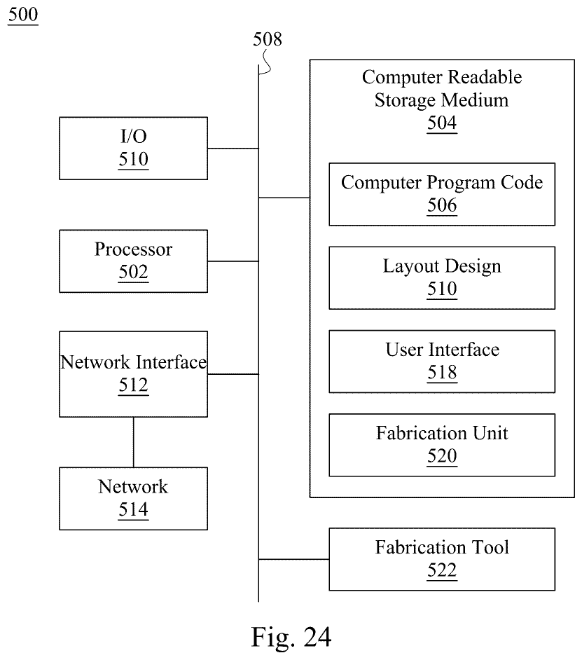

In operation 410 of the method 400, a layout design of a semiconductor device is generated. The operation 410 is performed by a processing device (e.g., processor 502 of FIG. 24) configured to execute instructions for generating a layout design. In one approach, the layout design is generated by placing layout designs of one or more standard cells through a user interface. In one approach, the layout design is automatically generated by a processor executing a synthesis tool that converts a logic design (e.g., Verilog) into a corresponding layout design. In some embodiments, the layout design is rendered in a graphic database system (GDSII) file format. In some embodiments, the layout design includes one that is similar to any of the example layouts depicted in FIGS. 5-8, 11, 12, 15, 16, 19, and 20, each depicting an embodiment of the memory device 100C described herein.

In operation 420 of the method 400, a semiconductor device is manufactured based on the layout design. In some embodiments, the operation 420 of the method 400 includes manufacturing at least one mask based on the layout design, and manufacturing a semiconductor device based on the at least one mask. Example manufacturing operations of the operation 420 may include patterning, implantation, deposition, etching, planarization, the like, or combinations thereof, to form a plurality of front-end-of-line device features (e.g., the active regions 20/22, the source/drain features 24/26, the metal gate structures 30/32, the gate isolation structures 40, the active region isolation structures 50, etc.), device-level (or middle-end-of-line) contacts (e.g., the frontside/backside source/drain contacts 70/82, the inter-tier source/drain contacts 72, the frontside/backside gate contacts 74/84, etc.), interconnect structures (or back-end-of-line structures; e.g., the frontside/backside via contacts 78/86/88, etc.), and metal lines (or back-end-of-line structures; e.g., the frontside/backside metal lines 80/92/90, etc.).

In some embodiments, the method 400 is implemented as a standalone software application for execution by a processor. In some embodiments, the method 400 is implemented as a software application that is a part of an additional software application. In some embodiments, the method 400 is implemented as a plug-in to a software application. In some embodiments, the method 400 is implemented as a software application that is a portion of an EDA tool. In some embodiments, the method 400 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated based on a netlist which is created based on the schematic design.

FIG. 24 is a schematic view of a system 500 for designing and manufacturing an IC layout design, in accordance with some embodiments. The system 500 generates or places one or more IC layout designs, as described herein. In some embodiments, the system 500 manufactures one or more semiconductor devices based on the one or more IC layout designs, as described herein. The system 500 includes a (e.g., hardware) processor 502 and a non-transitory, computer readable storage medium 504 encoded with, e.g., storing, computer program code 506, e.g., a set of executable instructions. The computer readable storage medium 504 is configured to interface with manufacturing machines for producing the semiconductor device. The processor 502 is electrically coupled to the computer readable storage medium 504 by a bus 508. The processor 502 is also electrically coupled to an I/O interface 510 by the bus 508. A network interface 512 is also electrically connected to the processor 502 by the bus 508. Network interface 512 is connected to a network 514, so that the processor 502 and the computer readable storage medium 1504 can connect to external elements via network 514. The processor 502 is configured to execute the computer program code 506 encoded in the computer readable storage medium 504 to cause the system 500 to be usable for performing a portion or all of the operations as described in method 400.

In some embodiments, the processor 502 is a central processing unit (CPU), a multi-processor, a distributed processing system, an application specific integrated circuit (ASIC), and/or a suitable processing unit. In some embodiments, the computer readable storage medium 504 is an electronic, magnetic, optical, electromagnetic, infrared, and/or a semiconductor system (or apparatus or device). For example, the computer readable storage medium 504 includes a semiconductor or solid-state memory, a magnetic tape, a removable computer diskette, a random-access memory (RAM), a read-only memory (ROM), a rigid magnetic disk, and/or an optical disk. In some embodiments using optical disks, the computer readable storage medium 504 includes a compact disk-read only memory (CD-ROM), a compact disk-read/write (CD-R/W), and/or a digital video disc (DVD).

In some embodiments, the computer readable storage medium 504 stores the computer program code 506 configured to cause the system 500 to perform the method 400. In some embodiments, the computer readable storage medium 504 also stores information needed for performing the method 400 as well as information generated during the performance of the method 400, such as layout design 516, user interface 518, fabrication unit 520, and/or a set of executable instructions to perform the operation of method 400.

In some embodiments, the computer readable storage medium 504 stores instructions (e.g., the computer program code 506) for interfacing with manufacturing machines. The instructions (e.g., the computer program code 506) enable the processor 502 to generate manufacturing instructions readable by the manufacturing machines to effectively implement the method 400 during a manufacturing process.

The system 500 includes the I/O interface 510. The I/O interface 510 is coupled to external circuitry. In some embodiments, the I/O interface 510 includes a keyboard, keypad, mouse, trackball, trackpad, and/or cursor direction keys for communicating information and commands to the processor 502.

The system 500 also includes the network interface 512 coupled to the processor 502. The network interface 512 allows the system 1500 to communicate with the network 514, to which one or more other computer systems are connected. The network interface 512 includes wireless network interfaces such as BLUETOOTH, WIFI, WIMAX, GPRS, or WCDMA; or wired network interface such as ETHERNET, USB, or IEEE-13154. In some embodiments, the method 400 is implemented in two or more systems 500, and information such as layout design, user interface and fabrication unit are exchanged between different systems 500 by the network 514.

The system 500 is configured to receive information related to a layout design through the I/O interface 510 or network interface 512. The information is transferred to the processor 502 by the bus 508 to determine a layout design for producing an IC. The layout design is then stored in the computer readable storage medium 504 as the layout design 516. The system 500 is configured to receive information related to a user interface through the I/O interface 510 or network interface 512. The information is stored in the computer readable storage medium 504 as the user interface 518. The system 500 is configured to receive information related to a fabrication unit through the I/O interface 510 or network interface 512. The information is stored in the computer readable storage medium 504 as the fabrication unit 520. In some embodiments, the fabrication unit 520 includes fabrication information utilized by the system 500.

In some embodiments, the method 400 is implemented by a manufacturing device to manufacture an integrated circuit using a set of masks manufactured based on one or more layout designs generated by the system 500. In some embodiments, the system 500 includes a manufacturing device (e.g., fabrication tool 522) to manufacture an integrated circuit using a set of masks manufactured based on one or more layout designs of the present disclosure. In some embodiments, the system 500 of FIG. 24 generates layout designs of an IC that are smaller than other approaches. In some embodiments, the system 500 of FIG. 24 generates layout designs of a semiconductor device that occupy less area than other approaches.

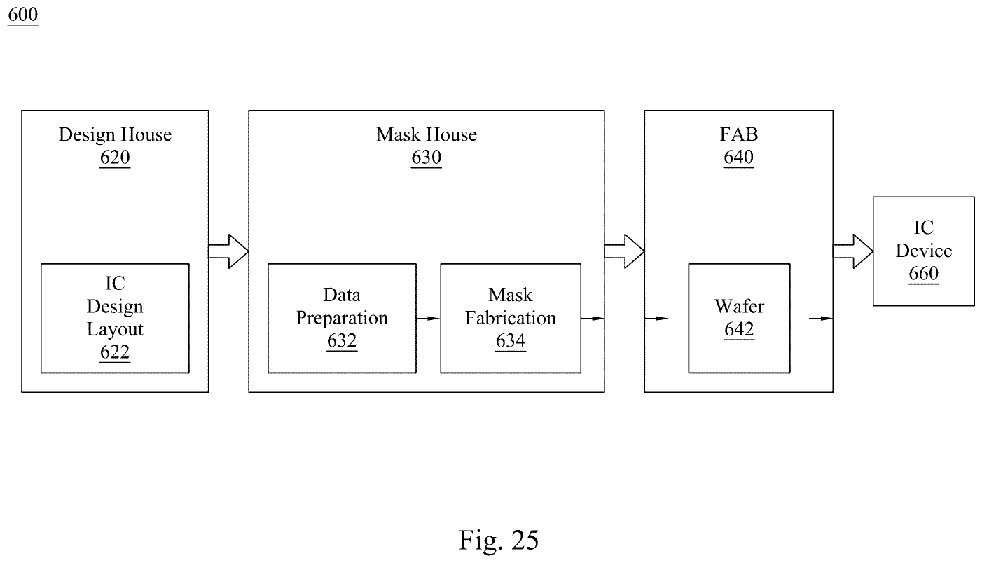

FIG. 25 is a block diagram of an integrated circuit (IC)/semiconductor device manufacturing system 600, and an IC manufacturing flow associated therewith, in accordance with at least one embodiment of the present disclosure.

In FIG. 25, the IC manufacturing system 600 includes entities, such as a design house 620, a mask house 630, and an IC manufacturer/fabricator (“fab”) 640, that interact with one another in the design, development, and manufacturing cycles and/or services related to manufacturing an IC device (semiconductor device) 660 (e.g., corresponding to any of the memory devices 100A-100C). The entities in the IC manufacturing system 600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 620, mask house 630, and IC fab 640 is owned by a single company. In some embodiments, two or more of design house 620, mask house 630, and IC fab 640 coexist in a common facility and use common resources.

The design house (or design team) 620 generates an IC design layout 622. The IC design layout 622 includes various geometrical patterns designed for the IC device 660. The geometrical patterns correspond to patterns of metal, oxide, or semiconductor layers that make up the various components of the IC device 660 to be fabricated. The various layers combine to form various IC features. For example, a portion of the IC design layout 622 includes various IC features, such as an active region, gate structures, source/drain regions, interconnect structures, and openings for bonding pads, to be formed in a semiconductor substrate (such as a silicon wafer) and various material layers disposed on the semiconductor substrate. The design house 620 implements a proper design procedure to form the IC design layout 622. The design procedure includes one or more of logic design, physical design or place and route. The IC design layout 622 is presented in one or more data files having information of the geometrical patterns. For example, the IC design layout 622 can be expressed in a GDSII file format or DFII file format.

The mask house 630 includes mask data preparation 632 and mask fabrication 634. The mask house 630 uses the IC design layout 622 to manufacture one or more masks to be used for fabricating the various layers of the IC device 660 according to the IC design layout 622. The mask house 630 performs the mask data preparation 632, where the IC design layout 622 is translated into a representative data file (“RDF”). The mask data preparation 632 provides the RDF to the mask fabrication 634. The mask fabrication 634 includes a mask writer. A mask writer converts the RDF to an image on a substrate, such as a mask (reticle) or a semiconductor wafer. The design layout is manipulated by the mask data preparation 632 to comply with particular characteristics of the mask writer and/or requirements of the IC fab 640. In FIG. 25, the mask data preparation 632 and mask fabrication 634 are illustrated as separate elements. In some embodiments, the mask data preparation 632 and mask fabrication 634 can be collectively referred to as mask data preparation.

In some embodiments, the mask data preparation 632 includes optical proximity correction (OPC) which uses lithography enhancement techniques to compensate for image errors, such as those that can arise from diffraction, interference, other process effects and the like. OPC adjusts the IC design layout 622. In some embodiments, the mask data preparation 632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 632 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 634, which may undo part of the modifications performed by OPC in order to meet mask creation rules.

In some embodiments, the mask data preparation 632 includes lithography process checking (LPC) that simulates processing that will be implemented by the IC fab 640 to fabricate the IC device 660. LPC simulates this processing based on the IC design layout 622 to create a simulated manufactured device, such as the IC device 660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 622.

It should be understood that the above description of the mask data preparation 632 has been simplified for the purposes of clarity. In some embodiments, the mask data preparation 632 includes additional features such as a logic operation (LOP) to modify the IC design layout according to manufacturing rules. Additionally, the processes applied to the IC design layout 622 during the mask data preparation 632 may be executed in a variety of different orders.

After the mask data preparation 632 and during mask fabrication 634, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 634 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 640 is an IC fabrication entity that includes one or more manufacturing facilities for the fabrication of a variety of different IC products. In some embodiments, the IC fab 640 is a semiconductor foundry. For example, there may be a first manufacturing facility for the front-end fabrication of a plurality of IC products (e.g., the active regions 20/22, the source/drain features 24/26, the metal gate structures 30/32, the gate isolation structures 40, the active region isolation structures 50, etc.), while a second manufacturing facility may provide the middle-end fabrication for the interconnection of the IC products (e.g., the frontside/backside source/drain contacts 70/82, the inter-tier source/drain contacts 72, the frontside/backside gate contacts 74/84, etc.) and a third manufacturing facility may provide the back-end fabrication for the interconnection and packaging of the IC products (e.g., the frontside/backside via contacts 78/86/88, the frontside/backside metal lines 80/92/90, etc.), and a fourth manufacturing facility may provide other services for the foundry entity.

The IC fab 640 uses the mask (or masks) fabricated by the mask house 630 to fabricate the IC device 660. Thus, the IC fab 1640 at least indirectly uses the IC design layout 622 to fabricate the IC device 660. In some embodiments, a semiconductor wafer 642 is fabricated by the IC fab 640 using the mask (or masks) to form the IC device 660. The semiconductor wafer 642 includes a silicon substrate or other proper substrate having material layers formed thereon. Semiconductor wafer further includes one or more of various doped regions, dielectric features, multilevel interconnects, and the like (formed at subsequent manufacturing steps).

The IC manufacturing system 600 is shown as having the design house 620, mask house 630, and IC fab 640 as separate components or entities. However, it should be understood that one or more of the design house 620, mask house 630, and IC fab 640 are part of the same component or entity.

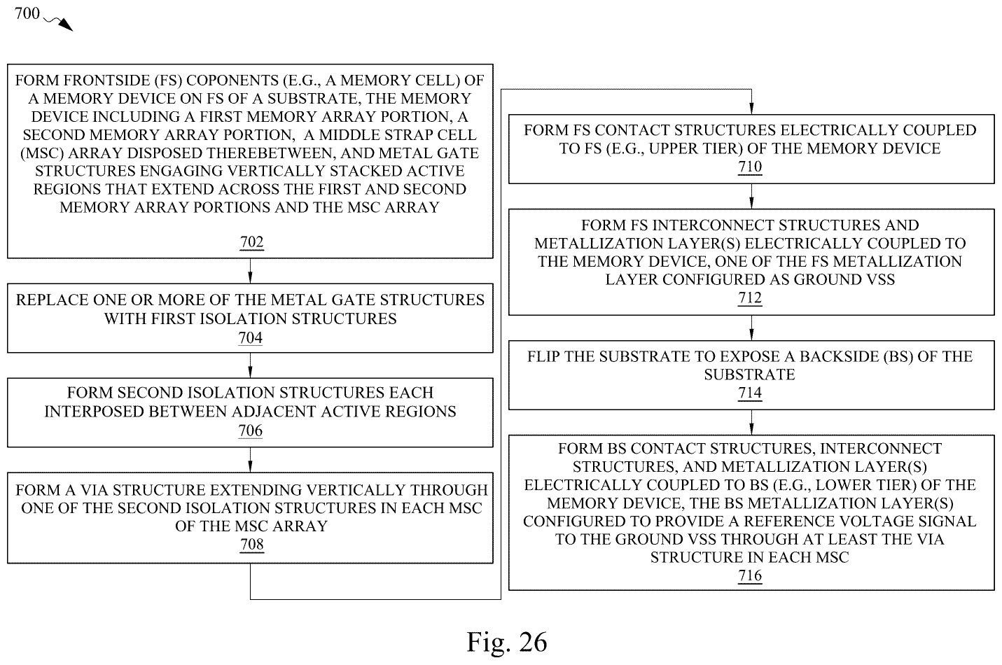

FIG. 26 illustrates a flowchart of a method 700 for forming a semiconductor device (e.g., any of the memory devices 100A-100C described above), in portion or in entirety, according to one or more embodiments of the present disclosure. It is noted that the method 700 is merely an example and is not intended to limit the present disclosure. Accordingly, it is understood that additional operations may be provided before, during, and after the method 700, and that some other operations may only be briefly described herein.

Referring to FIG. 26, components of a memory device (e.g., any of the memory devices 100A-100C) is formed on a frontside of a substrate (e.g., the substrate 12) at operation 702. The memory device includes a first memory array portion (e.g., the first array portions 102A, 104A), a second memory array portion (e.g., the second array portions 102B, 104B), and a middle strap cell array (MSC array; e.g., the MSC arrays 152A, 154A) disposed therebetween along the first direction. The memory device further includes a plurality of metal gate structures (e.g., the metal gate structures 30, 32) engaging vertically stacked active regions (e.g., the lower active regions 20 and the upper active regions 22) that extend across the first memory array portion, the second memory array portion, and the MSC array. In some embodiments, each of the memory array portions includes a plurality of memory cells (e.g., the memory cell 10), while the MSC array includes a plurality of MSCs each aligned with the neighboring memory cells along the first direction.

In some embodiments, a portion or an entirety of each of the memory cells corresponds to a semiconductor memory device 900 (hereafter referred to as device 900) described below that may be fabricated by a method 800, according to one or more embodiments of the present disclosure. In this regard, consistent with the description regarding the memory devices 100A-100C and the device 900, the memory devices provided herein each include a plurality of upper transistors (e.g., an upper transistor 910U) vertically stacked over a plurality of lower transistors (e.g., a lower transistor 910L) along the third direction.

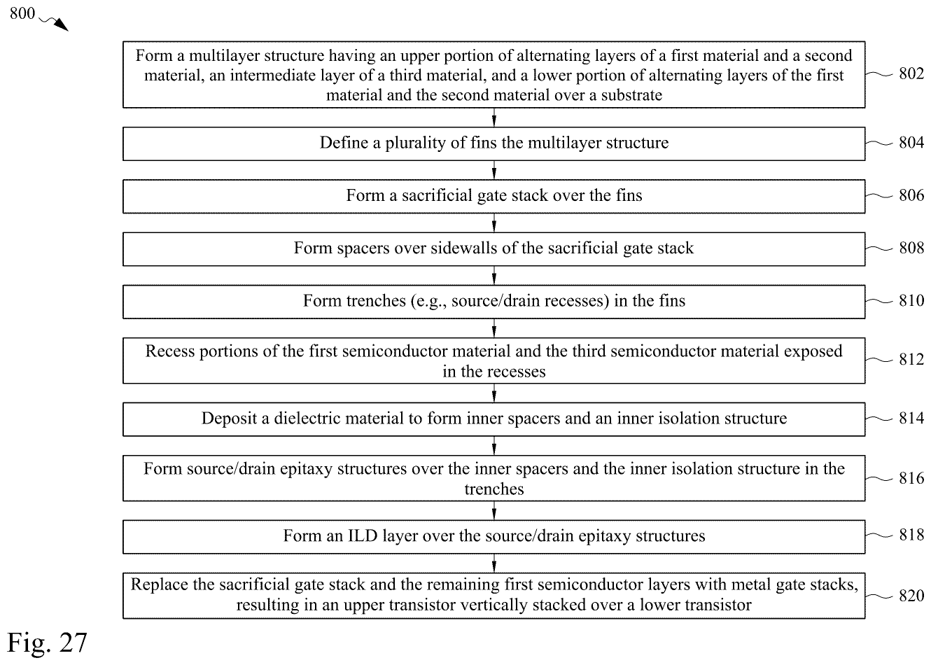

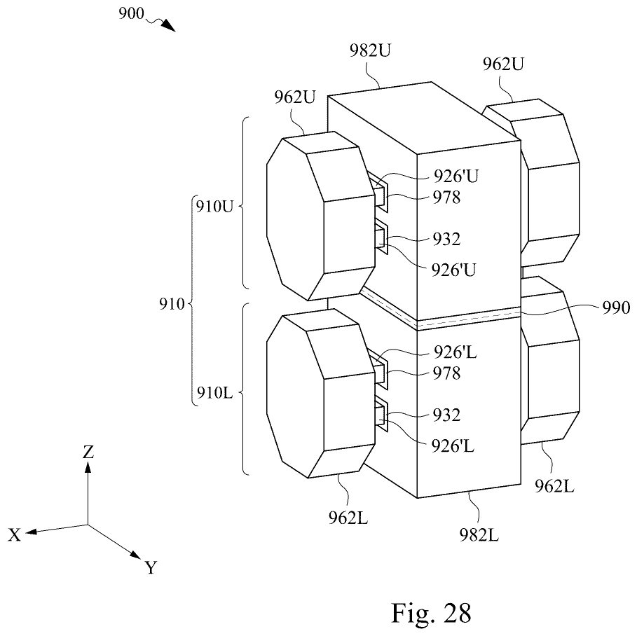

FIG. 27 illustrates a flowchart of the method 800 for forming the device 900. In some embodiments, the method 800 may be implemented at the operation 702 described above. It is noted that the method 800 is merely an example and is not intended to limit the present disclosure. Accordingly, it is understood that additional operations may be provided before, during, and after the method 800, and that some other operations may only be briefly described herein. In some embodiments, operations of the method 800 may be associated with perspective and cross-sectional views of the device 900 at various fabrication stages as shown in FIGS. 28-33, which are discussed in detail below.

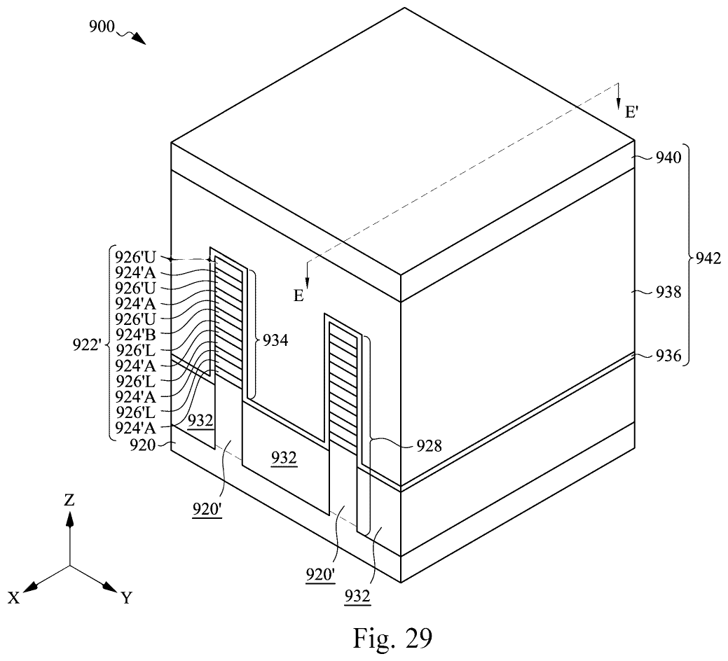

Referring to FIGS. 27 and 29, a multilayer structure (e.g., a multilayer structure 922′) of alternating first semiconductor layers (e.g., first semiconductor layers, or nanosheets, 924′A, 924′B) and second semiconductor layers (e.g., second semiconductor layers, or nanosheets, 926′U, 926′L) is formed over a substrate (e.g., a substrate 920) at operation 802. Specifically, the multilayer structure includes an upper portion having alternating first semiconductor material (e.g., the first semiconductor layers 924′A) and second semiconductor material (e.g., the second semiconductor layers 926′U); a lower portion having alternating first semiconductor material and second semiconductor material (e.g., the second semiconductor layers 926′L); and an intermediate layer of a third semiconductor material (e.g., a middle first semiconductor layer 924′B) different from the first semiconductor material and the second semiconductor material in composition. The intermediate layer of the third semiconductor material is interleaved between two layers (e.g., middle second semiconductor layers 926′M) of the second semiconductor material that are configured as dummy layers.

A plurality of fins (e.g., fins 928; alternatively referred to as active regions) are defined in the multilayer structure at operation 804 by one or more etching processes. Isolation structures (e.g., isolation structures 932) may be formed over the substrate and between the fins. Subsequently, still referring to FIGS. 27 and 29, a sacrificial gate structure (e.g., the sacrificial gate structure 942) including a sacrificial gate dielectric layer (e.g., the sacrificial gate dielectric layer 936), a sacrificial gate electrode layer (e.g., the sacrificial gate electrode layer 938), and a mask structure (e.g., a mask structure 940) is formed over the fins at operation 806.

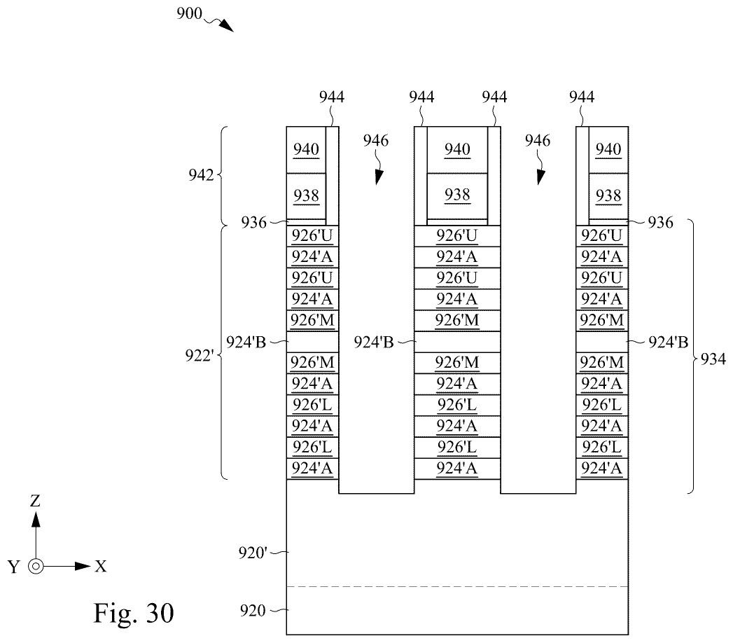

Referring to FIGS. 27 and 30, corresponding spacers (e.g., spacers 944) are then formed over sidewalls of the sacrificial gate structure 942 at operation 808. Trenches (e.g., trenches 946; also referred to as source/drain recesses) are formed in each of the fins at operation 810. Exposed portions of the first semiconductor material (e.g., exposed edge portions of each of the first semiconductor layers 924A′) and an entirety of the third semiconductor material (e.g., the middle first semiconductor layer 924B′) in the trenches are then recessed to form intermediate openings at operation 812. The second semiconductor material (e.g., the second semiconductor layers 926′U, 926′L) remain substantially intact during the recessing at operation 812. Subsequently, a dielectric material is deposited in the trenches to form inner spacers (e.g., inner spacers 954) and an inner isolation structure (e.g., inner isolation structure 956) at operation 814.

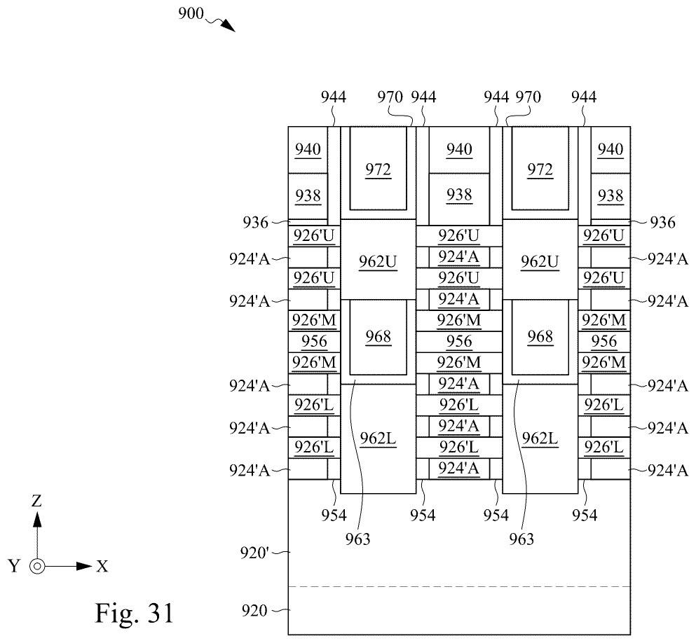

Referring to FIGS. 27 and 31, lower source/drain epitaxy structures (e.g., source/drain epitaxy structures 962L) and upper source/drain epitaxy structure (e.g., source/drain epitaxy structures 962U), collectively referred to as source/drain epitaxy structures, are formed over the inner spacers and the inner isolation structures in the trenches at operation 816. In some embodiments, a liner (e.g., liner 963) and a dielectric material (e.g., dielectric material 968) are formed over upper surfaces of the lower source/drain epitaxy structures before forming the upper epitaxy structures. An ILD layer (e.g., ILD layer 972) is then formed over the source/drain epitaxy structures at operation 818. In some embodiments, a CESL (e.g., CESL 970) is formed over the source/drain epitaxy structures before forming the ILD layer. A chemical mechanical polishing (CMP) process is subsequently performed to planarize the CESL and/or the ILD layer.

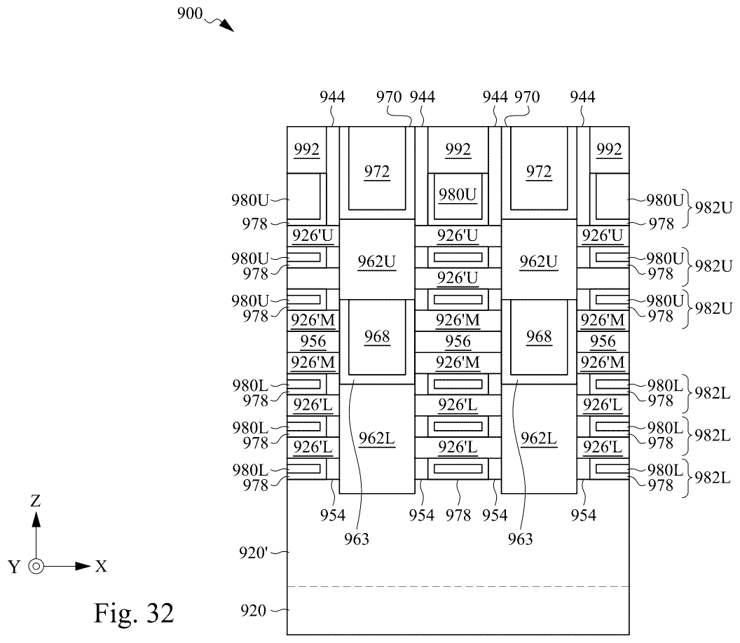

Subsequently, referring to FIGS. 27 and 32, the sacrificial gate structure and the remaining portions of the first semiconductor layers (e.g., remaining portions of the first semiconductor layers 924A′) are replaced with metal gate structures that each include a gate dielectric layer (e.g., gate dielectric layer 978) and a gate electrode (e.g., gate electrode 980U and gate electrode 980L) at operation 820. In the depicted embodiment, the gate structures formed in the upper portion of the device 900, i.e., above the inner isolation structure 956, are referred to as upper gate structures (e.g., upper gate structures 982U) that each include the gate electrode 980U, and the gate structures formed in the lower portion of the device 900, i.e., below the inner isolation structure 956, are referred to as lower gate structures (e.g., lower gate structures 982L) that each include the gate electrode 980L.

FIG. 28 illustrates a schematic perspective view of an embodiment of the device 900, in portion or in entirety, according to some embodiments of the present disclosure. The device 900 may be fabricated using the method 800 described with reference to FIG. 27. The device 900 may correspond to a portion of the memory cell 10 of any of the memory devices 100A-100C described herein. The device 900 includes a multilayer structure 910 of the lower (or first) transistor 910L and an upper (or second) transistor 910U. The lower transistor 910L is over and above a substrate 920 (see FIG. 29). The upper transistor 910U is physically stacked over the lower transistor 910L along the third direction as depicted in FIG. 28. In this regard, the lower transistor 910L is disposed between the substrate 920 and the upper transistor 910U along the third direction.

In some embodiments, the upper transistor 910U and the lower transistor 910L are of different conductivity types. In one such example, the upper transistor 910U is an NMOS device and the lower transistor 910L is a PMOS device, and the multilayer structure 910 is referred to as a N-on-P structure (e.g., an N-on-P CFET). In another such example, the upper transistor 910U is a PMOS transistor and the lower transistor 910L is an NMOS transistor, and the multilayer structure 910 is referred to as a P-on-N structure (e.g., a P-on-N CFET). In some embodiments, the upper transistor 910U and the lower transistor 910L are of the same conductivity type, such as both are of n-type (forming an N-on-N structure) or both are of p-type (forming a P-on-P structure). In the present embodiments, the upper transistor 910U may correspond to one of the PD1 or PD2 of the memory cell 10 of any of the memory devices 100A-100C, and the lower transistor 910L may correspond to one of the PU1 or PU2 of the memory cell 10 of any of the memory devices 100A-100C.

In some embodiments, the upper transistor 910U and the lower transistor 910L are each configured as a multi-channel device, such as a nanosheet transistor, nanowire transistor, or the like. In the example configuration depicted herein, the upper transistor 910U and lower transistor 910L are nanosheet transistors. Other device configurations may also be applicable to embodiments of the present disclosure.

The upper transistor 910U includes a metal gate structure 982U, and source/drain epitaxy structures 962U on opposite sides of the metal gate structure 982U along the first direction. The metal gate structure 982U extends, or is elongated, along a second direction. The first direction, second direction, third direction are mutually transverse to each other. In some embodiments, the first direction, second direction, third direction are mutually perpendicular to each other. The upper transistor 910U further includes a channel region configured by nanosheets 926′U (also referred to as the second semiconductor layers 926U′) which extend along the first direction and connect the source/drain epitaxy structures 962U. In some embodiments, the nanosheet 926′U corresponds to each nanosheet of the upper active region 22. In the example configuration in FIG. 28, the upper transistor 910U includes two nanosheets 926′U. Other numbers of nanosheets per transistor are within the scopes of various embodiments. The upper transistor 910U includes a gate dielectric layer 978 extending around each of the nanosheets 926′U, and electrically isolating the metal gate structure 982U from the nanosheets 926′U. The metal gate structure 982U extends around the gate dielectric layer 978 and nanosheets 926′U in a configuration referred to as a gate-all-around (GAA) configuration. Other gate configurations are within the scopes of various embodiments.

The lower transistor 910L includes the metal gate structure 982L, the source/drain epitaxy structures 962L, a channel region configured by the nanosheets 926′L (also referred to as the second semiconductor layers 926′L), and the gate dielectric layer 978 extending around each of the nanosheets 926′L. The metal gate structure 982L, the source/drain epitaxy structures 962L, and the nanosheets 926′L are vertically aligned with the metal gate structure 982U, the source/drain epitaxy structures 962U, and the nanosheets 926′U. The metal gate structure 982U, the source/drain epitaxy structures 962U, and the nanosheets 926′U correspondingly overlap the metal gate structure 982L, the source/drain epitaxy structures 962L, and the nanosheets 926′L along the third direction. In the example configuration in FIG. 28, the source/drain epitaxy structures 962U, 962L include epitaxy structures of different conductivity types. For example, the source/drain epitaxy structures 962U include n-type doped epitaxy structures, and the source/drain epitaxy structures 962L include p-type doped epitaxy structures. In some embodiments, the source/drain epitaxy structures 962U, 962L include epitaxy structures of the same conductivity type.

In some embodiments, the nanosheet 926′L corresponds to each nanosheet of the lower active region 20, the metal gate structure 982L and the gate dielectric layer 978 collectively correspond to the metal gate structures 30, and the source/drain epitaxy structures 962L correspond to the source/drain features 24. Analogously, the nanosheet 926′U corresponds to each nanosheet of the upper active region 22, the metal gate structure 982U and the gate dielectric layer 978 collectively correspond to the metal gate structures 32, and the source/drain epitaxy structures 962U correspond to the source/drain features 26.

The multilayer structure 910 further includes an intermediate layer 990 between the metal gate structure 982U and metal gate structure 982L. In some embodiments, the intermediate layer 990 includes a dielectric layer and is configured as a gate isolation structure (similar to the gate isolation structures 160 and 280) electrically isolating the metal gate structure 982U from the metal gate structure 982L, in a configuration referred to as an isolated gate configuration in which the metal gate structure 982U and metal gate structure 982L are controllable independently from each other.

As can be seen in the CFET structures provided herein, such as the memory devices 100A-100C, the stacking of one transistor (e.g., the PD1 of the memory device 10) over another FET (e.g., the PU1 of the memory device 10) saves about 50% of the required chip area, compared to other approaches without stacking of semiconductor devices. In some embodiments, it is possible to manufacturing an IC device comprising multiple device stacks by CFET processes, with little or no changes to the manufacturing processes.

FIG. 29 is a schematic perspective view of the device 900 in accordance with some embodiments. The device 900 comprises a plurality of device stacks formed on the substrate 920, which corresponds to the substrate 12. In some embodiments, the substrate 920 is a semiconductor substrate. In some embodiments, the substrate 920 includes a single crystalline semiconductor layer on at least the surface of the substrate 920. The substrate 920 may have a composition similar to that described above with respect to the substrate of the device 200.

The multilayer structure 922′ is formed over the substrate 920. In FIG. 29, the multilayer structure 922′ is illustrated in a state after formation of fins, as described herein. The multilayer structure 922′ includes alternatingly arranged first semiconductor layers 924′A, 924′B and second semiconductor layers 926′U (i.e., the nanosheets 926U′ of FIGS. 28), 926′L. The second semiconductor layers 926′U, 926′L correspond to the nanosheets described with respect to FIG. 28 and are referred to herein by the same reference numerals of the nanosheets, for simplicity. The first semiconductor layers 924′A, 924′B and the second semiconductor layers 926′U, 926′L include semiconductor materials having different etch selectivity and/or oxidation rates. For example, in some embodiments the first semiconductor layers 924′A, 924′B include SiGe, and the second semiconductor layers 926′U, 926′L include Si. In some embodiments, the first semiconductor layers 924′A, 924′B have different concentrations of Ge, resulting in different etch selectivity and/or oxidation rates therebetween. In some embodiments, the first and second semiconductor layers 924′A, 924′B, 926′U, 926′L are formed by a deposition process, such as epitaxy. For example, epitaxial growth of the layers of the multilayer structure 922′ is performed by a molecular beam epitaxy (MBE) process, a metalorganic chemical vapor deposition (MOCVD) process, and/or other suitable epitaxial growth processes.

Subsequent to the formation of the multilayer structure 922′, the fins 928 are formed. In some embodiments, each fin 928 corresponds to a pair of the lower active region 20 and the upper active region 22 vertically aligned along the third direction. Each fin 928 includes a substrate portion 920′ of the substrate 920, and a portion 934 of the multilayer structure 922′. The portion 934 of the multilayer structure 922′ is sometimes referred to as a stack of semiconductor layers 934. In some embodiments, the fins 928 are fabricated using suitable processes, such as double-patterning or multi-patterning processes. For example, in one or more embodiments, a sacrificial layer is formed over a substrate and patterned using a photolithography process. Spacers are formed alongside the patterned sacrificial layer using a self-aligned process. The sacrificial layer is then removed, and the remaining spacers are then used to pattern the fins 928 by etching the multilayer structure 922′ and the substrate 920. Example etch processes include, but are not limited to, dry etch, wet etch, reactive ion etch (RIE), and/or other suitable processes. In FIG. 29, two fins 928 are illustrated; however, the number of the fins is not limited to two. In the present embodiments, the fins 928 extend, or are elongated, along the first direction across multiple portions over the substrate 920, such as the first array portion (e.g., the first array portion 102A or 104A), the second array portion (e.g., the second array portion 102B or 104B), and the MSC array (e.g., the MSC array 152A, 152B, 152C, 154A, 154B, or 154C).

In some embodiments, the isolation structures 932 including an insulating material are formed over the substrate 920 and in trenches (not depicted) between the fins 928. In some embodiments, the isolation structures 932 correspond to the isolation structures 14. For example, the insulating material is deposited over the substrate 920 and the fins 928. Example insulating materials of the isolation structures 932 include, but are not limited to, silicon oxide (SiO₂), fluorine-doped silicate glass (FSG), silicon nitride (SiN), silicon oxynitride (SiON), silicon oxycarbonitride (SiOCN), silicon carbonitride (SiCN), a low-k dielectric material, the like, or combinations thereof. The deposition of the insulating material includes a suitable method, such as low-pressure chemical vapor deposition (LPCVD), plasma enhanced CVD (PECVD) or flowable CVD (FCVD). Then, a planarization operation, such as a CMP process and/or an etch-back process, is performed such that the tops of the fins 928 are exposed from the insulating material. A portion of the insulating material between adjacent fins 928 is removed. The remaining portion of the insulating material configures the isolation structures 932. The partial removal of the insulating material includes dry etch, wet etch, or the like.

In some embodiments, the sacrificial (or dummy) gate dielectric layer 936, the sacrificial (or dummy) gate electrode layer 938, and the mask structure 940 are deposited over the isolation structures 932 and fins 928. In some embodiments, the sacrificial gate dielectric layer 936 comprises one or more layers of dielectric material, such as SiO₂, SiN, a high-k dielectric material, the like, or combinations thereof. In some embodiments, the sacrificial gate dielectric layer 936 is deposited by a CVD process, a sub-atmospheric CVD (SACVD) process, a FCVD process, an atomic layer deposition (ALD) process, a physical vapor deposition (PVD) process, or other suitable process. In at least one embodiment, the sacrificial gate electrode layer 938 comprises polycrystalline silicon (polysilicon). In some embodiments, the mask structure 940 comprises a multilayer structure. In some embodiments, the sacrificial gate electrode layer 938 and the mask structure 940 are formed by one or more processes such as layer deposition, for example, CVD (including both LPCVD and PECVD), PVD, ALD, thermal oxidation, e-beam evaporation, or other suitable deposition techniques to obtain the device 900.

Referring to FIG. 30, the sacrificial gate structures 942 are formed by one or more pattern and/or etch processes performed on the deposited sacrificial gate dielectric layer 936, sacrificial gate electrode layer 938, and mask structure 940. An example pattern process comprises a lithography process. An example etch process comprises dry etch (e.g., RIE), wet etch, other etch methods, and/or combinations thereof. Each sacrificial gate structure 942 comprises a portion of each of the sacrificial gate dielectric layer 936, sacrificial gate electrode layer 938, and mask structure 940. The sacrificial gate structures 942 extend, or are elongated, along the second direction. In FIG. 30, three sacrificial gate structures 942 are illustrated; however, the number of the sacrificial gate structures 942 is not limited to two.

The spacers 944 are formed on sidewalls of the sacrificial gate structures 942. For example, the spacers 944 are formed by first depositing a conformal layer that is subsequently etched back to form the spacers 944. The spacers 944 comprises a dielectric material, such as SiO₂, SiN, silicon carbide, silicon oxycarbide, SiON, SiCN, SiOCN, the like, or combinations thereof. In some embodiments, the spacers 944 comprise multiple layers.

Exposed portions of the stack of semiconductor layers 934 of the fins 928 not covered by the sacrificial gate structures 942 and the spacers 944 are selectively removed, e.g., by one or more suitable etch processes, such as dry etch, wet etch, or a combination thereof, to form the trenches 946. In FIG. 30, a lower most one of the second semiconductor layers 926′U and an uppermost one of the second semiconductor layers 926′L are designated as the middle second semiconductor layers 926′M which sandwich therebetween the middle first semiconductor layer 924′B. The middle second semiconductor layers 926′M and the middle first semiconductor layer 924′B are not configured to form channel regions of the upper transistor 910U and lower transistor 910L. Edge portions of the first semiconductor layers 924′A, 924′B and second semiconductor layers 926′U, 926′L, 926′M are exposed in the trenches 946. The trenches 946 also expose portions of the substrate portion 920′ and obtain the device 900 as depicted in FIG. 30.

Referring to FIG. 31, the exposed edge portions of the first semiconductor layers 924′A are replaced. In some embodiments, the removal comprises a selective wet etch process. The selective wet etch process further completely (or substantially completely) removes the first semiconductor layer 924′B in the middle of the stack of semiconductor layers 934. For example, in embodiments where the first semiconductor layers 924′A, 924′B include SiGe, and the second semiconductor layers 926′U, 926′L, 926′M include Si, a selective wet etch is configured to etch the first semiconductor layer 924′B at a highest etch rate, the first semiconductor layers 924′A at a second highest etch rate, and the second semiconductor layers 926′U, 926′L, 926′M at a slowest etch rate. As a result, the exposed edge portions of each of the first semiconductor layers 924′A and an entirety (or substantially an entirety) of each of the first semiconductor layer 924′B are removed, whereas the second semiconductor layers 926′U, 926′L, 926′M are substantially unchanged.

A dielectric material is deposited over and into the spaces created by the removal of the first semiconductor layer 924′B and the partial removal of the edge portions of the first semiconductor layers 924′A. The dielectric material filling in the spaces created by the partial removal of the edge portions of the first semiconductor layers 924′A configures the inner spacers 954. The dielectric material filling in the space created by the removal of the first semiconductor layer 924′B configures the inner isolation structure 956. Examples of the dielectric material forming the inner spacers 954 and inner isolation structure 956 include, but are not limited to, a low-k dielectric material, such as SiO₂, SiN, SiCN, SiOC, or SiOCN, or a high-k dielectric material, such as HfO₂, ZrOx, ZrAlOx, HfAlOx, HfSiOx, AlOx, or other suitable dielectric material. In some embodiments, the inner spacers 954 and inner isolation structure 956 comprise different dielectric materials. In an example process, the inner spacers 954 and inner isolation structure 956 are formed by depositing a conformal layer of the dielectric material, using a conformal deposition process, such as ALD, followed by an anisotropic etching to remove portions of the conformal layer other than the inner spacers 954 and inner isolation structure 956.

The source/drain epitaxy structures 962L are formed over, and in contact with, the exposed portions of the substrate portions 920′, and exposed edge portions of the second semiconductor layers 926′L. In the example configuration in FIG. 31, the source/drain epitaxy structures 962L include epitaxy structures and are hereafter alternatively referred to as source/drain epitaxy structures 962L. In some embodiments, similar to any of the devices 100A-100C described herein, the source/drain epitaxy structures 962L include one or more layers of silicon germanium doped with a p-type dopant described herein to configure a PMOS transistor as the lower transistor 910L. In some embodiments, the epitaxy structures 962L includes one or more layers of silicon or silicon carbon doped with an n-type dopant described herein to configure an NMOS transistor as the lower transistor 910L. Example epitaxial growth processes for growing the source/drain epitaxy structures 962L include, but are not limited to, CVD, ALD, MBE. In some embodiments, source/drain epitaxy structures 962L are grown to a height above the uppermost second semiconductor layer 926′L, and then top portions of the source/drain epitaxy structures 962L are partially removed, e.g., by a dry etch or wet etch, so that upper surfaces of the remaining source/drain epitaxy structures 962L are at a level of the uppermost first semiconductor layer 924′A immediately under the lower middle second semiconductor layer 926′M, as illustrated in FIG. 31.

The liner 963 is formed at least over the upper surfaces of the source/drain epitaxy structures 962L, and exposed side faces of the middle second semiconductor layers 926′M, inner isolation structure 956. In some embodiments, the liner 963 comprises silicon. In an example process, the liner 963 is a conformal layer formed by a conformal process, such as an ALD process.

The dielectric material 968 is formed over the liner 963 and over the source/drain epitax y structures 962L. In some embodiments, the dielectric material 968 comprises the same material as the isolation structures 932 and/or is formed by the same method as the isolation structures 932. The liner 963 and dielectric material 968 are removed outside the trenches 946, and partially removed inside the trenches 946, e.g., by a dry etch or wet etch. As a result, upper surfaces of the liner 963 and dielectric material 968 are at a level of the lowermost first semiconductor layer 924′ A immediately above the upper middle second semiconductor layer 926′M, as illustrated in FIG. 31. The liner 963 and dielectric material 968 configure an isolation structure between the source/drain epitaxy structures 962L and the source/drain epitaxy structures 962U to be subsequently formed thereover.

Source/drain epitaxy structures 962U are formed over, and in contact with, the upper surfaces of the liner 963 and dielectric material 968, and exposed edge portions of the second semiconductor layers 326U. In the example configuration in FIG. 31, the source/drain epitaxy structures 962U comprise epitaxy structures and are sometimes referred to as source/drain epitaxy structures 962U. In some embodiments, the source/drain epitaxy structures 962U are of a different conductivity type from that of the source/drain epitaxy structures 962L. In some embodiments, the source/drain epitaxy structures 962U are manufactured by the same manufacturing processes as the source/drain epitaxy structures 962L. In at least one embodiment, the source/drain epitaxy structures 962U have the same configuration, e.g., the same size, shape, height, material, as the source/drain epitaxy structures 962L. In some embodiments, similar to any of the devices 100A-100C described herein, where the source/drain epitaxy structures 962L comprise one or more layers of silicon germanium doped with a p-type dopant to configure a PMOS transistor, the source/drain epitaxy structures 3962U comprise one or more layers of silicon or silicon carbon doped with a n-type dopant to configure an NMOS transistor. In some embodiments, where the source/drain epitaxy structures 962L comprise one or more layers of silicon or silicon carbon doped with a n-type dopant to configure an NMOS transistor, the source/drain epitaxy structures 3962U comprise one or more layers of silicon germanium doped with a p-type dopant to configure a PMOS transistor.

In some embodiments, source/drain epitaxy structures 962U are grown to a height above the sacrificial gate dielectric layer 936, and then top portions of the source/drain epitaxy structures 962U are partially removed, e.g., by a dry etch or wet etch, so that upper surfaces of the remaining source/drain epitaxy structures 962U are at a level of the sacrificial gate dielectric layer 936, as illustrated in FIG. 31. This is an example, and a height of the source/drain epitaxy structures 962U is controllable depending on application and/or process requirements.

The CESL 970 is formed over the source/drain epitaxy structures 962U. Example materials of the CESL 970 include, but are not limited to, silicon nitride, silicon carbon nitride, silicon oxynitride, carbon nitride, silicon oxide, silicon carbon oxide, the like, or a combination thereof. The CESL 970 is formed by CVD, PECVD, ALD, or any suitable deposition technique.

The ILD layer 972 is formed over the CESL 970. Example materials of the ILD layer 972 include, but are not limited to, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 972 is deposited by a PECVD process or other suitable deposition technique to obtain the device 900 as depicted in FIG. 31.

Referring to FIG. 32, a planarization process, such as a CMP process, is performed to remove the mask structure 940 and expose the sacrificial gate electrode layer 938. The planarization process also removes portions of the ILD layer 972 and the CESL 970. The exposed sacrificial gate electrode layer 938 and the sacrificial gate dielectric layer 936 are removed, e.g., by one or more suitable processes, such as dry etch, wet etch, or a combination thereof.

Next, the first semiconductor layers 924′A are removed, e.g., by any suitable processes, such as dry etch, wet etch, or a combination thereof. The removal of the first semiconductor layers 924′A exposes the inner spacers 954 and the second semiconductor layers 926′U, 926′L, and creates spaces between and around exposed portions of the second semiconductor layers 926′U, 926′L not covered by the inner spacers 954. The exposed portions of the second semiconductor layers 926′U, 926′L configure the nanosheets 926′U, 926′L described with respect to FIG. 28. The middle second semiconductor layers 926′M and inner isolation structure 956 are covered by the liner 963 and dielectric material 968 and are substantially unaffected by the removal of the first semiconductor layers 924′A.

The gate dielectric layer 978 is formed over and around each of the nanosheets 926′U, 926′L. In some embodiments, the gate dielectric layer 978 includes the same material as the sacrificial gate dielectric layer 936. In some embodiments, the gate dielectric layer 978 comprises a high-k dielectric material. In some embodiments, the gate dielectric layer 978 is formed by a conformal process, such as an ALD process.

The gate electrode 980U is formed over and around the gate dielectric layers 978, and the nanosheets 926′U, 926′L. The gate electrode 980U surrounds each of the nanosheets 926′U, i.e., is disposed above the inner isolation structure 956, and is configured to form each upper metal gate structure 982U. The gate electrode 980L surrounds each of the nanosheets 926′L, i.e., is disposed below the inner isolation structure 956, is configured to form each lower metal gate structure 982L. In some embodiments, the gate electrodes 980U and 980L each include, but are not limited to, polysilicon, Al, Cu, Ti, Ta, W, Co, Mo, nickel silicide, cobalt silicide, TaN, TiN, WN, WCN, TiAl, TiTaN, TiAlN, TaN, TaCN, TaC, TaSiN, metal alloys, the like, or combinations thereof. In some embodiments, the gate electrode material includes one or more work function metals. Example processes for depositing the gate electrode material include, but are not limited to, PVD, CVD, ALD, electro-plating, or other suitable methods.

In some embodiments, each of the gate electrode 980U and gate electrode 980L is configured to form a corresponding nanosheet structure, and the upper gate structures 982U and the lower gate structures 982L may be partially separated from each other by the middle second semiconductor layers 926′M and inner isolation structure 956. In some embodiments, a combination of the middle second semiconductor layers 926′M and inner isolation structure 956 corresponds to the intermediate layer 990 being a dielectric material in an isolated gate configuration. The formation of the gate electrode 980U and gate electrode 980L completes the formation of the upper transistor 910U and the lower transistor 910L in a front-end-of-line (FEOL) fabrication process.

Continuing with operation 704 of the method 700, referring to FIG. 26, one or more of the metal gate structures in the memory device are replaced with first isolation structures (e.g., the active region isolation structures 40), which truncate or isolate the vertically stacked active regions. For example, referring to FIGS. 7 and 8, the metal gate structures 30 in the upper tier and the corresponding metal gate structures 32 in the lower tier located near the vertical boundaries 11B between the memory cell 10 and the MSC 150 are respectively replaced with the active region isolation structures 40A and 40B. In the present embodiments, the vertically stacked active regions and the first isolation structures each extend continuously across the memory cell in the memory array portions and the MSC disposed therebetween.

In some embodiments, replacing the metal gate structures includes forming a patterned mask over the substrate, where the patterned mask exposes the metal gate structures to be removed. The patterned mask may include a photoresist layer capable of being patterned using a photolithography technique. Subsequently, the exposed metal gate structures are removed to form trenches using a suitable etching process, such as dry etch, wet etch, reactive ion etch (RIE), or other suitable processes. The patterned mask may then be removed using any suitable method, such as plasma ashing or resist stripping. A dielectric layer including a suitable material, such as SiO₂, SiN, the like, or combinations thereof, is then deposited in the trenches using a suitable deposition process, such as CVD, ALD, PVD, the like, or combinations thereof. The dielectric layer is planarized using a CMP process, resulting in the first isolation structures that are substantially coplanar with the metal gate structures.

At operation 706, second isolation structures (e.g., the gate isolation structures 50) are formed over the metal gate structures and the first isolation structures, which truncate or separate the metal gate structures in the upper tier and the lower tier. In some embodiments, the second isolation structures each extend across the memory array portions and the MSC along the first direction and is disposed between two adjacent active regions along the second direction. For example, referring to FIGS. 7 and 8, each gate isolation structure 50 is disposed over the isolation structures 14 and between two adjacent upper and lower active regions 20 and 22, thereby truncating each of the corresponding metal gate structures 30 and 32 into portions arranged along the second direction.

At operation 708, a via structure (e.g., the VLI 60) is formed in a portion of one of the second isolation structures in the MSC. The via structure extends through the second isolation structure along the third direction and is thus embedded in or surrounded by the second isolation structure. For example, referring to FIGS. 7-10, the VLI 60 is formed in or over the extended portion 61 of the gate isolation structure 50A and extends vertically between the backside metal line 90G and the frontside metal line 80C along the third direction.

In some embodiments, the via structure is formed simultaneously or concurrently with the second isolation structure. For example, forming the second isolation structure and the via structure includes removing portions of the metal gate structures and the isolation structures over the substrate to form a trench extending along the first direction and between two adjacent active regions. In the present embodiments, the trench includes an extended portion having a height along the second direction that is greater than a height of the portions of the trench outside the extended portion. Subsequently, a dielectric layer including a suitable dielectric material similar to that of the first isolation structure is deposited in the trench, thereby partially filling the extended portion of the trench. Thereafter, a conductive material is deposited over the trench to completely fill the extended portion, resulting in the via structure surrounded by the dielectric layer. Any portions of the dielectric material and the conductive material are then planarized using one or more CMP processes, for example, to form the via structure formed in the extended portion of the trench.

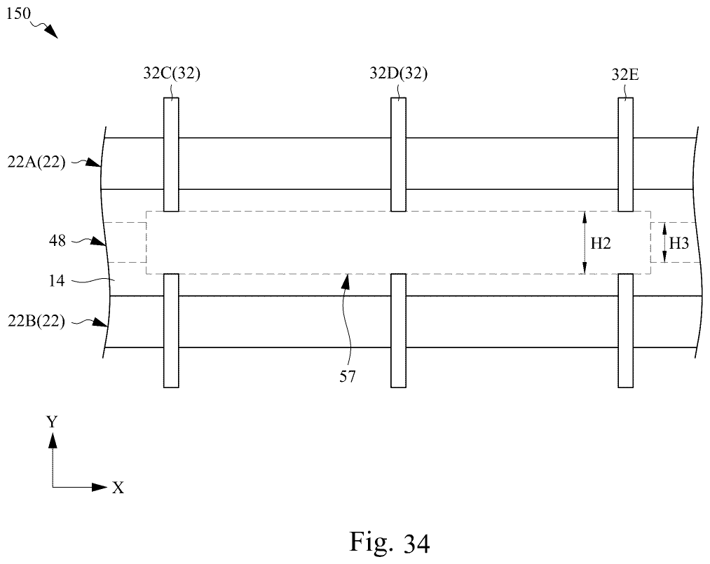

Using the memory device 100C as an example, each of FIGS. 34-36 depicts a portion of the layout of the MSC 150 in a top view of the frontside of the substrate 12, similar to the view of FIG. 7. In some embodiments, referring to FIG. 34, forming the gate isolation structure 50 and the VLI 60 includes patterning the metal gate structures 32 and the isolation structures 14 to form a trench 48 using a series of photolithography and etching techniques similar to those described above with respect to forming the first isolation structure. The trench 48 extends into the isolation structures 14 along the third direction. The trench 48 includes an extended portion 57 having a height H2 along the second direction. The portions of the trench 48 outside the extended trench has a height H3 that is generally less than the height H2.

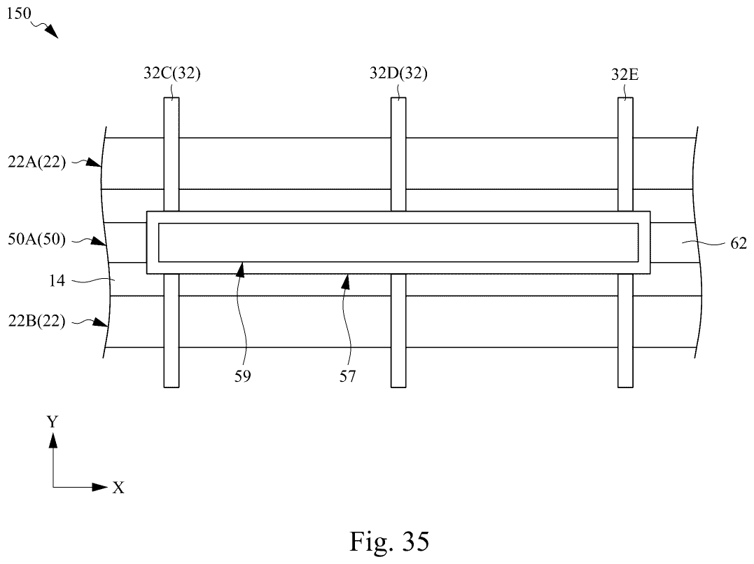

Referring to FIG. 35, a dielectric layer 62, which may include any suitable dielectric material, such as SiO₂, SiN, the like, or combinations thereof, is deposited in the trench 48 including the extended portion 57. In some embodiments, the deposition process is an isotropic and conformal deposition process implemented using CVD or any other suitable method. Due to the difference between the height H2 and the height H3, depositing the dielectric layer 62 fills the portions of the trench 48 outside the extended portion 57 first, leaving a cavity 59 in the extended portion 57 surrounded by the conformal dielectric layer 62.

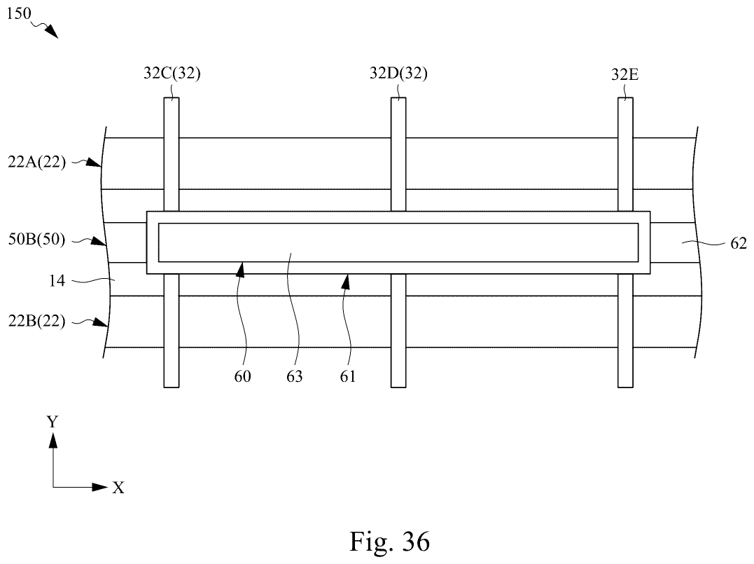

Referring to FIG. 36, a conductive layer 63 is deposited over the trench 48, thereby completely filling the cavity 59. The conductive layer 63 may include any suitable conductive material, such as W, Cu, Co, Ru, Al, Ti, Ta, TiN, TaN, Pt, the like, or combinations (or alloys) thereof, and may be deposited using any suitable process, such as CVD, ALD, PVD, plating, the like, or combinations thereof. Subsequently, one or more CMP processes may be performed to remove any excess dielectric layer 62 and conductive layer 63 to planarize a top surface of the gate isolation structure 50A and the VLI 60.

Alternatively, in some embodiments, the via structure is formed after forming the second isolation structure. For example, after forming the trench 48, the dielectric layer 62 may be first deposited to completely fill the trench 48, which includes the extended portion 57. The dielectric layer 62 may then be planarized using a CMP process and patterned to form the cavity 59 using a series of photolithography and etching techniques described herein. The conductive layer 63 may be subsequently deposited to fill the cavity 59 and planarized such that a top surface of the VLI 60 is substantially coplanar with a top surface of the gate isolation structure 50A.

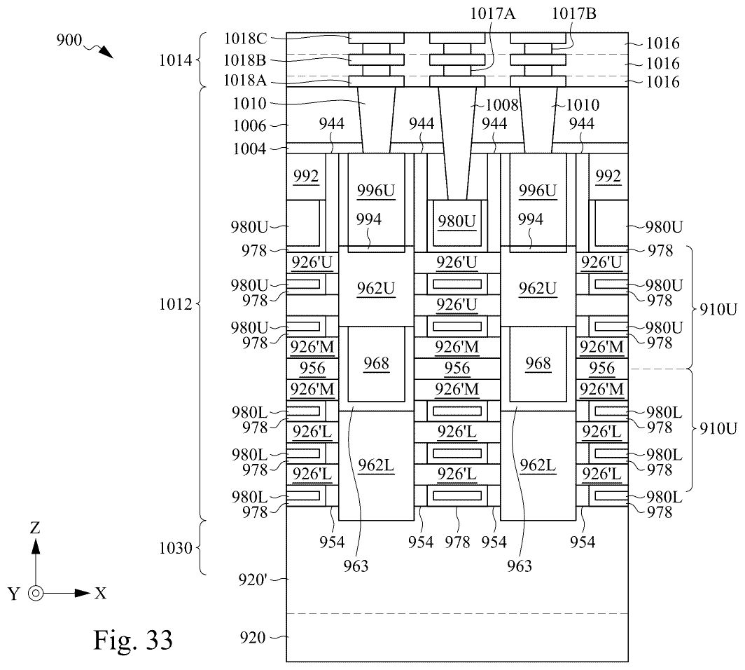

At operation 710, frontside contact structures are formed over and electrically coupled to the frontside of the memory device, including upper transistors of the memory device in each memory cell and the via structure in each MSC. Using the device 900 depicted in FIG. 33 as an example, the frontside contact structures may include frontside source/drain contacts 996U (e.g., the frontside source/drain contacts 70) electrically coupled to at least some of the source/drain epitaxy structures 962U (e.g., the source/drain features 26) in the upper tier of the device 900 from the frontside of the substrate 920. The contact structures may further include frontside gate contacts 1008 (e.g., the frontside gate contacts 74, etc.) electrically coupled to the upper metal gate structures 982U from the frontside of the substrate 920.

In some embodiments, forming the frontside source/drain contacts 996U includes patterning the ILD layer 972 to form trenches exposing the source/drain epitaxy structures 962U. A silicide layer 994 is formed over the exposed source/drain epitaxy structures 962U in the trench, and then the frontside source/drain contacts 996U are form in each trench and over the silicide layer 994. Example conductive materials of the frontside source/drain contacts 996U include Cu, Co, Ru, Al, Ti, Ta, TiN, TaN, Pt, the like, or combinations (or alloys) thereof. The conductive material of the frontside source/drain contacts 996U may be deposited by any suitable process, such as PVD, ECP, or CVD, and planarized by a CMP process, for example. In some embodiments, though not depicted herein, frontside source/drain contacts similar to the frontside source/drain contacts 996U are also formed over and electrically coupled to the via structure formed in the MSC (see FIGS. 7-10). For example, the frontside source/drain contacts 70H and 70I are formed over and electrically coupled to the VLI 60 in the MSC 150.

Similarly, continuing with the device 900 as an example, forming the frontside gate contacts 1008 may include forming a mask structure 992 over the upper metal gate structures 982U, a CESL 1004 over the mask structure 992, and an ILD layer 1006 over the CESL 1004. Compositions of the mask structure 992, the ILD layer 1006 and the CESL 1004 may be analogous to those of the mask structure 940, the ILD layer 972 and the CESL 970, respectively. The stack of the mask structure 992, the ILD layer 1006, and the CESL 1004 is then patterned to form trenches in which the frontside gate contacts 1008 are formed by a series of deposition and planarization techniques described above with respect to forming the frontside source/drain contacts 996U.

At operation 712, frontside interconnect structures and metallization layers are formed over and electrically coupled to the frontside contact structures of the memory device. Using the device 900 depicted in FIG. 33 as an example, forming frontside via contacts 1010 (e.g., the frontside via contacts 78) may include patterning the stack of the mask structure 992, the ILD layer 1006, and the CESL 1004 to form via openings, and then filling the via openings with a conductive material described above. The conductive material may subsequently be planarized using a CMP process, resulting in the frontside via contacts 1010.

Thereafter, still referring to FIG. 33 as an example, a multilayer interconnect (MLI) structure 1014 over and electrically coupled to the frontside gate contacts 1008 and the frontside source/drain contacts 996U, for example. The MLI structure 1014 includes a plurality of frontside metal lines 1018A (e.g., the frontside metal lines 80 in the frontside metallization layer M0), 1018B (e.g., the frontside metal lines 92 in the frontside metallization layer M1), and 1018C, and frontside via contacts 1017A (e.g., the frontside via contacts 89) and 1017B sequentially and alternately formed over the frontside gate contacts 1008 and the frontside via contacts 1010. In some embodiments, the frontside metal lines 1018A are formed in the metallization layer M0, the frontside metal lines 1018B immediately over the frontside metal lines 1018A are formed in the metallization layer M1, and so on. The MLI structure 1014 further includes various ILD layers 1016 in which the metal lines and the via contacts are embedded. Although not depicted herein, additional dielectric layers, frontside via contacts, and frontside metal lines may be formed over the frontside metal lines 1018C as a part of the MLI structure 1014.

In some embodiments, a plurality of the frontside metal lines 1018A of the MLI structure 1014 respectively correspond to the ground VSS, the BL, the BLB, and optionally, the WL, as depicted in FIGS. 3A, 3B, and 7-22. In this regard, each of the frontside metal lines 1018A is configured to electrically couple to one or more of the transistors of the device 900, such as the upper transistors 910U, in a manner similar to electrical connection between the components of the memory devices 100A-100C as depicted in FIGS. 1-22. In some embodiments where the upper transistor 910U is configured as an NMOS transistor (corresponding to the PD1 or the PD2) and the lower transistor 910L is configured as a PMOS transistor (corresponding to the PU1 or PU2 of the memory cell 10), the supply voltage VDD is configured as a backside metal line in a backside metallization layer BM0 described herein.

In the present embodiments, using the device 100C depicted in FIGS. 7-22 as an example, a first subset of the frontside source/drain contacts 70, the frontside via contacts 78, and the frontside metal lines 80 are formed over and electrically coupled to the upper transistors in each memory cell 10, while a second subset of the frontside source/drain contacts 70, the frontside via contacts 78, and the frontside metal lines 80 are formed over and electrically coupled to the VLI 60 in each MSC 150 at the operation 712. As described herein, no electrical connection is formed between portions of the MSC 150 and the frontside metal lines 80 that correspond to the BL, the BLB, or the WL, if present, on the frontside of the memory device.

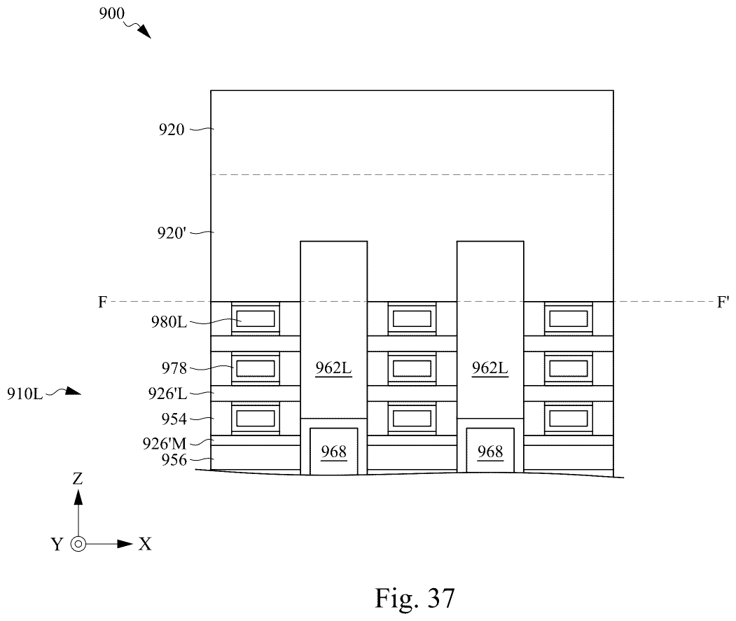

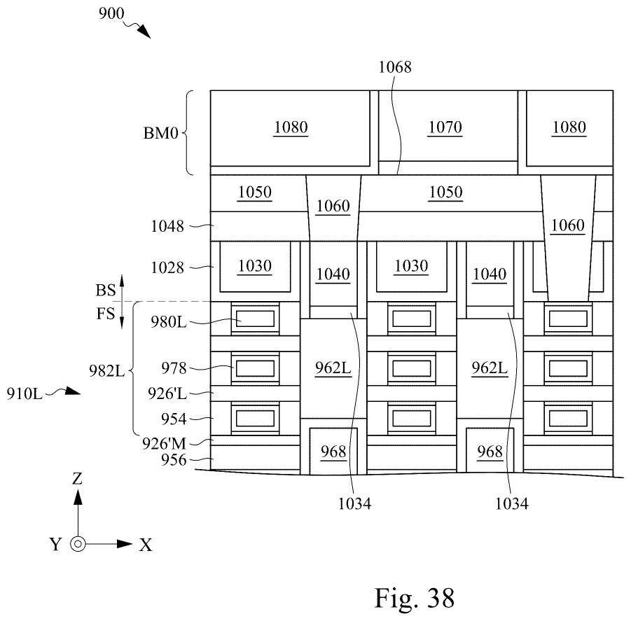

At operation 714, the substrate is flipped to expose the backside of the substrate in preparation for fabricating the backside components of the memory device. Using the device 900 depicted in FIG. 37 as an example, the flipped substrate 920 may be polished along line FF′ using a CMP process, for example, to remove excess portions of the substrate 920 and expose a backside of the lower transistors 910L.

At operation 716, backside contact structures, interconnect structures, and metallization layers analogous to those on the frontside of the memory device are formed over and electrically coupled to the backside of the lower transistors in each memory cell as well as the backside of the via structure in each MSC. The backside contact structures, interconnect structures, and metallization layers may be formed in processes similar to those of the corresponding frontside features and are thus only briefly described below.

Using the device 900 depicted in FIG. 38 as an example, dielectric layers 1028 and 1030 are formed on the backside of the lower transistor 910L. The dielectric layers 1028 and 1030 are patterned to form trenches in which a silicide layer 1034 and backside source/drain contacts 1040 (e.g., the backside source/drain contacts 82) over the silicide layer 1034 are formed. In this regard, the backside source/drain contacts 1040 are electrically coupled to the backside of the source/drain epitaxy structures 962L (e.g., the source/drain features 24). Subsequently, dielectric layers 1048 and 1050, analogous to the dielectric layers 1028 and 1030, respectively, are formed over the backside source/drain contacts 1040. The dielectric layers 1048 and 1050 are patterned to form trenches in which backside via contacts 1060 (e.g., the backside via contacts 88 and 86) are formed and electrically coupled to the respective backside source/drain contacts 1040. Thereafter, dielectric layers 1068 and 1070, analogous to the dielectric layers 1028 and 1030, respectively, are formed over the backside via contacts 1040. The dielectric layers 1068 and 1070 are then patterned to form trenches in which backside metal lines 1080 (e.g., the backside metal lines 90) are formed as portions of a backside metallization layer BM0. Although not depicted herein, additional dielectric layers, backside via contacts, and backside metal lines may be formed over the backside metal lines 1080.

In the present embodiments, using the device 100C depicted in FIGS. 7-22 as an example, a first subset of the backside source/drain contacts 82, the backside via contacts 88, and the backside metal lines 90 are formed over and electrically coupled to the lower transistors in each memory cell 10, while a second subset of the backside source/drain contacts 82, the backside via contacts 88, and the backside metal lines 90 are formed over and electrically coupled to the VLI 60 in each MSC 150 at the operation 716. In the present embodiments, the backside metal lines 90 may be configured, in portion or in entirety, as the PDN of the memory device responsible for providing the reference voltage signal to the ground VSS on the frontside of the memory device (e.g., as one of the frontside metal lines 80) through the VLI 60 in each MSC 150.

Although the structures and methods will be discussed in terms of CFET structures devices, one of ordinary skill in the art would understand that the structures and methods are not so limited and certain aspects of the embodiments discussed are suitable for inclusion in manufacturing processes for other classes and configurations of IC devices. The structures and methods disclosed herein are equally applicable to various manufacturing processes used in achieving the vertical stack structures including both monolithic CFET manufacturing processes and sequential CFET manufacturing processes.

It will be understood that not all advantages have been necessarily discussed herein, no particular advantage is required for all embodiments or examples, and other embodiments or examples may offer different advantages.

In one aspect, the present disclosure provides a device. The device includes a substrate including a frontside and a backside opposite the frontside. The device includes a cell array disposed over the substrate. The cell array includes a first array portion and a second array portion separated along a first direction in a top view of the device. Each of the first array portion and the second array portion includes a plurality of cells. The device includes a middle strap cell array disposed between the first array portion and the second array portion along the first direction. The middle strap cell array includes a plurality of middle strap cells arranged along a second direction perpendicular to the first direction in the top view. Each middle strap cell includes a via structure configured to deliver a reference voltage signal from the backside of the substrate to the frontside of the substrate.

In another aspect, the present disclosure provides a device. The device includes a first cell disposed over a frontside of a substrate, the frontside opposite to a backside of the substrate. The device includes a second cell disposed over the frontside of the substrate and spaced from the first cell along a first direction in a top view of the device. The device includes a first metal line disposed over the frontside of the substrate and electrically coupled to the first cell and the second cell. The device includes a second metal line disposed over the backside of the substrate. The device includes a middle strap cell interposed between and aligned with the first cell and the second cell along the first direction. The middle strap cell includes a via structure electrically coupling the first metal line to the second metal line.

In yet another aspect, the present disclosure provides a method of fabricating a device. The method includes forming a first array portion, a second array portion, and a middle strap cell array in a device, the middle strap cell array interposed between the first array portion and the second array portion along a first direction. The first array portion, the second array portion, and the middle strap cell array include a first active region and a second active region each extending along the first direction over a frontside of a substrate and spaced apart along a second direction perpendicular to the first direction in a top view of the device. The first active region and the second active region provide a first cell in the first array portion, a second cell in the second array portion, and a middle strap cell in the middle strap cell array. The first array portion, the second array portion, and the middle strap cell array further include a third active region extending along the first direction and vertically stacked below the first active region along a third direction perpendicular to the first direction and the second direction. The method includes forming a first metal line above the first active region and the second active region along the third direction, the first metal line electrically coupled to the first active region and the second active region. The method includes forming a second metal line over the backside of the substrate, the second metal line electrically coupled to the third active region, and the via structure electrically coupled to the second metal line and the first metal line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device, comprising:
a substrate including a frontside and a backside opposite the frontside;
a cell array disposed over the substrate, the cell array including a first array portion and a second array portion separated along a first direction in a top view of the device, each of the first array portion and the second array portion including a plurality of cells; and
a middle strap cell array disposed between the first array portion and the second array portion along the first direction, the middle strap cell array including a plurality of middle strap cells arranged along a second direction perpendicular to the first direction in the top view, and each middle strap cell including a via structure configured to deliver a reference voltage signal from the backside of the substrate to the frontside of the substrate.

2. The device of claim 1, wherein each cell includes:
a first active region and a second active region each extending along the first direction and spaced apart along the second direction, and
a gate isolation structure disposed between the first active region and the second active region, wherein the via structure is disposed in the gate isolation structure.

3. The device of claim 2, wherein the via structure has a first height extending along the second direction, and wherein the gate isolation structure includes an extended portion having a second height extending along the second direction, the second height being greater than the first height.

4. The device of claim 2, wherein each cell further includes a third active region disposed below and aligned with the first active region along a third direction perpendicular to the first direction and the second direction.

5. The device of claim 1, wherein each cell has a first height extending along the second direction, and wherein each middle strap cell has a second height extending along the second direction, the second height being the same as the first height.

6. The device of claim 1, wherein each middle strap cell is aligned along the first direction with a first cell in the first array portion and a second cell in the second array portion.

7. The device of claim 1, wherein the via structure is centered in each middle strap cell along each of the first direction and the second direction.

8. The device of claim 1, further comprising an active region isolation structure extending along the second direction and disposed between the via structure of each middle strap cell and an adjacent cell in the first array portion or the second array portion.

9. A device, comprising:
a first cell disposed over a frontside of a substrate, the frontside opposite to a backside of the substrate;
a second cell disposed over the frontside of the substrate and spaced from the first cell along a first direction in a top view of the device;
a first metal line disposed over the frontside of the substrate and electrically coupled to the first cell and the second cell;
a second metal line disposed over the backside of the substrate; and
a middle strap cell interposed between and aligned with the first cell and the second cell along the first direction, the middle strap cell including a via structure electrically coupling the first metal line to the second metal line.

10. The device of claim 9, wherein the first metal line is configured as a ground for the first cell and the second cell, and wherein the second metal line is configured to provide a reference voltage signal to the first metal line through the via structure.

11. The device of claim 10, wherein the first cell includes:
a first active region extending along the first direction, a second active region extending parallel to the first active region, and an isolation structure extending parallel to the first active region and interposed between the first active region and the second active region along a second direction perpendicular to the first direction in the top view, wherein the via structure extends through the isolation structure in the middle strap cell along a third direction perpendicular to the first direction and the second direction.

12. The device of claim 11, wherein the first cell further includes a third active region disposed below and aligned with the first active region along the third direction.

13. The device of claim 12, wherein the first active region and the third active region are configured to provide an upper transistor and a lower transistor, respectively, having different conductivity types.

14. The device of claim 13, further comprising:
a first source/drain contact disposed on the frontside of the substrate and electrically coupled to the upper transistor;
a first via contact disposed on the frontside of the substrate and electrically coupled to the first source/drain contact and the first metal line;
a second source/drain contact disposed on the backside of the substrate and electrically coupled to the lower transistor; and
a second via contact disposed on the backside of the substrate and electrically coupled to the second source/drain contact and the second metal line.

15. The device of claim 11, wherein the isolation structure extends through a center of the first cell, the middle strap cell, and the second cell along the first direction.

16. The device of claim 9, wherein the first metal line extends through a center of the first cell, the middle strap cell, and the second cell along the first direction.

17. The device of claim 9, wherein the first metal line extends through a boundary of the first cell, the middle strap cell, and the second cell along the first direction.

18. A method, comprising:
forming a first array portion, a second array portion, and a middle strap cell array in a device, the middle strap cell array interposed between the first array portion and the second array portion along a first direction, the first array portion, the second array portion, and the middle strap cell array including:
a first active region and a second active region each extending along the first direction over a frontside of a substrate and spaced apart along a second direction perpendicular to the first direction in a top view of the device, wherein the first active region and the second active region provide a first cell in the first array portion, a second cell in the second array portion, and a middle strap cell in the middle strap cell array, and
a third active region extending along the first direction and vertically stacked below the first active region along a third direction perpendicular to the first direction and the second direction;
forming a via structure in the middle strap cell between the first active region and the second active region along the second direction, the via structure extending along the third direction between the frontside of the substrate and a backside of the substrate opposite to the frontside;
forming a first metal line above the first active region and the second active region along the third direction, the first metal line electrically coupled to the first active region and the second active region; and
forming a second metal line over the backside of the substrate, the second metal line electrically coupled to the third active region, and the via structure electrically coupled to the second metal line and the first metal line.

19. The method of claim 18, further comprising forming an isolation structure over the frontside of the substrate, the isolation structure extending along the first direction and between the second active region along the second direction such that the via structure is surrounded by the isolation structure.

20. The method of claim 19, wherein forming the isolation structure and forming the via structure are implemented simultaneously, including:
forming a trench extending along the first direction and disposed between the first active region and the second active region along the second direction, the trench including an extended portion having a first height along the second direction that is greater than a second height of portions of the trench outside the extended portion;
depositing a dielectric material in the trench, the dielectric material partially filling the extended portion;
depositing a conductive material over the dielectric material to completely fill the extended portion, resulting in the via structure surrounded by the dielectric material; and
planarizing the dielectric material and the conductive material to form the via structure surrounded by the isolation structure.
